(19) United States
(12) Patent Application Publication
(10) Pub. No.: US 2024/0128150 A1
(43) Pub. Date: Apr. 18, 2024

(54) SEMICONDUCTOR PACKAGE STRUCTURE FOR ENHANCED COOLING

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW)

(21) Appl. No.: 18/473,999

(22) Filed: Sep. 25, 2023

Related U.S. Application Data
(60) Provisional application No. 63/409,854, filed on Sep. 26, 2022.
(60) Provisional application No. 63/432,414, filed on Dec. 14, 2022.
(60) Provisional application No. 63/583,008, filed on Sep. 15, 2023.

(51) Int. Cl. H01L 23/367; H01L 23/00; H01L 23/498; H01L 25/065

(52) U.S. Cl. CPC H01L 23/3675; H01L 23/49822; H01L 23/49838; H01L 24/08; H01L 24/16; H01L 25/0655; H01L 2224/08137; H01L 2224/08146; H01L 2224/16157; H01L 2224/16227; H01L 2924/1433; H01L 2924/1436; H10B 80/00

(57) ABSTRACT

A semiconductor package is provided, which includes a processor die powered by either a front-side or a backside power delivery network, a plurality of memory dies and control dies stacked over the processor die, a plurality of high-thermal-conductivity interconnects located between and/or placed side-by-side with the dies, a substrate carrying all the dies with the substrate having a first cavity allowing a liquid to pass through, and a cold plate disposed over and in direct thermal contact with the top dies with the cold plate having a second cavity configured to connect to the first cavity and allowing the liquid to flow between the first and second cavities. This semiconductor package can be configured to go beyond the traditional single-sided interconnection and cooling topologies to enable dual- or multi-sided cooling, power supply, and signaling.

### PRIORITY CLAIM AND CROSS-REFERENCE

This application claims the benefit of prior-filed U.S. provisional application No. 63/409,854, filed on Sep. 26, 2022, prior-filed U.S. provisional application No. 63/432,414, filed on Dec. 14, 2022, and prior-filed U.S. provisional application No. 63/583,008, filed on Sep. 15, 2023 incorporates by reference herein in their entirety.

### FIELD

This disclosure relates in general to a semiconductor package structure for enhanced cooling, and particularly to a novel 2.5D IC and/or 3D IC package structures involving processor-memory interconnection that provide enhanced cooling.

### BACKGROUND

For high-end applications such as high-performance computing (HPC), data centers and AI (artificial intelligence), the requirement of compute power, memory bandwidth and memory capacity is huge and ever-increasing in order to handle the skyrocketing data traffic. This has led to the proliferation of 3D HBM (high-bandwidth memory) DRAM stacks we are witnessing today, which is practically the only high-volume, commercialized 3D IC today. 3D HBM DRAM stacks are typically placed side-by-side and co-packaged with a processor (or chiplets) on a 2.5D silicon interposer containing through-silicon vias (TSVs) in the 2.5D IC configuration. An alternative to the interposer is a laminate substrate containing embedded or substrate mounted silicon interconnect bridges. 3D HBM DRAM stacks typically contain 4, 8 or 12 DRAM ICs vertically stacked on a control logic IC for HBM1, HBM2 and HBM3, respectively. All dies in the HBM stacks contain TSVs with the exception of the top DRAM die.

3D HBM DRAM stacks for HPC, data centers and AI applications are typically placed much closer, within millimeters, to and are co-packaged with the processor in 2.5D ICs compared to traditional systems in which the processor and memory packages are mounted at much larger distances on the printed circuit board (PCB). In modern microelectronic systems, data moves back and forth between processor and DRAM which is the main memory for most chips. High-end processors today require and need to dissipate much higher power (e.g., up to 700 W/chip for GPUs as in the case of nVidia H100 and 400 W/chip for CPUs) compared to leading-edge HBMs (e.g., less than about 15 W for HBM3) and yesteryear's processors in traditional compute systems.

Moreover, driven by the continuing explosive growth of data traffic, processor powers are expected to continue to increase and are expected to exceed 1000 W/chip in the near future for data centers in particular. In contrast, 3D HBM DRAM systems offer lower power, higher bandwidth and higher density advantages compared to 2D memories mounted on the PCB. In a 3D HBM DRAM stack (for instance, in a HBM3 DRAM stack where 12 DRAM dies are stacked on a control die), the power per unit area can increase as a result of more-die stacking (with neighboring dies in the vertical stack heating each other) and the bottom and middle tiers DRAM typically have limited heat dissipation paths compared to dies on top of them which are closer to the heat spreader and heatsink in the case of air cooling or to cold plate in the case of direct-to-chip liquid cooling. Both factors can contribute to overheating of 3D devices (compared to 2D memories) with the hottest tiers at the bottom and the cooler tiers at the top. High temperatures in a DRAM can result in reduced performance and efficiency, especially when dynamic thermal management schemes are used to throttle DRAM bandwidth whenever temperature gets too high. Overheating can also cause the devices to be stalled, i.e., prevented from being accessed, as well as reliability issues. All electronic devices function reliably within a particular temperature range. To mitigate this for a 3D HBM DRAM, one can, for instance, map frequently accessed data on the top tiers such that the memory (particularly the bottom tiers) does not get overheated often to reduce the stalls, and reduce leakage power by migrating data from hot channels and then turning them off, and/or implement a stall-balanced policy for thermal management that enables distributed cooling, idling and decreased overheads when 3D memory is deployed in conjunction with a processor.

Both HBM DRAM stacks and 2.5D ICs are maxing out on their capabilities to reap the full benefits of processor performance advancement going forward particularly as the data traffic continues to soar. Going forward, the rate of advancement in processor speed will continue to exceed the rate of advancement in DRAM memory speed. The exponent for microprocessors is substantially larger than that for DRAMs although each is improving exponentially. As shown in FIG. 1, the interconnect bandwidth between processor and memory lags behind processor performance gains. This creates the “memory wall” effect which has prevented processor performance from being fully exploited. Memory latency and bandwidth will continue to limit system performance with sustained (streaming) memory bandwidth falling behind peak FLOP rates as shown in FIG. 1, which includes HBM1, HBM2 and one of nVidia's GPUs, A100. This imbalance has created a significant bottleneck that continues to grow larger each year while the industry continues to demand even more computing performance.

New generations of processors for machine learning, AI and analytics programs will require massive powers and generate substantial amounts of heat. Among these applications, data centers alone account for 1% to 1.5% of global electricity consumption (with servers at data centers responsible for about 40% of data center power consumption), and this percentage is expected to increase as cloud services, edge computing, IoT (internet-of-things), AI and other digital transformation technologies take hold. In order to deliver ever-higher performance to process the exponential increase in data traffic, processor chip power at data centers is expected to grow 5 times from 2018 to 2023, reaching 1000 W per chip with chips packaged in 2.5D IC, 3D IC and/or chiplets-in-SiP platforms as shown in FIG. 2. Certain AI applications such as Cerebra's 8″×8″ wafer-scale AI processor chip, the largest SoC ever built, already consumes an astounding 15 kW per chip. According to recent research and publication, the energy consumption of data centers and communication networks can amount to 17% of total electricity demand worldwide by 2030. In addition to escalating power consumption, data center power density requirements continue to increase year after year. The average rack power density is currently around 7 kW to 16 kW. With the wider adoption of HPC, data centers and AI applications, power densities can reach 100 kW per rack. Escalating data center power consumption and thermal management of high-power processor chips needs to be tackled while minimizing the compute-memory bandwidth gap in order to reap the full potential of the processor performance gains and minimize power consumption as the industry struggles with ever-higher processor power and associated cooling.

To mitigate the “memory wall” effect that comes with traditional compute systems involving processor and memory packages mounted on the printed circuit board (PCB), near-memory computing and in-memory computing have been proposed, as illustrated in FIG. 3. In FIG. 3, near-memory computing exemplified by 2.5D IC and in-memory computing through 3D IC involve moving memory from the PCB to near the processor in the same package (in the case of 2.5D IC) or better yet right on top of the processor in the same package (in the case of 3D IC). Recent work has shown that certain memories can morph themselves into compute units by exploiting the physical properties of the memory cells, enabling in-situ computing in the memory array. Both in- and near-memory computing can circumvent overheads related to data movement with techniques that enable efficient mapping of data-intensive applications to such devices. Using the 2.5D and 3D IC architectures, the “memory wall” effect between processing engines and the main storage, DRAM memory system, can be greatly alleviated through the low-latency, high-bandwidth connections to memory, afforded by the HBM stacks. The 3D IC architecture involving stacking HBM DRAM stacks on top of the processor in 3D IC is particularly attractive as it facilitates higher bandwidth between the HBM stacks and the processor, shorter data transfer time and lower power consumption compared to 2.5D ICs, while keeping other conditions identical. In line with the industry's drive towards near-/in-memory computing, the 3D HBM DRAM and processor in a 2.5D packaging architecture is migrating towards 3D IC, i.e., 3D memory-processor co-packaging in the vertical (package thickness) direction on a substrate. A case in point is AMD's 3D V-cache architecture for its EPYC Milan-X processors announced in 2022, which involves copper hybrid bonding a 64 MB SRAM on a CPU (central processing unit) processor. This trend to go 3D IC will ultimately enable logic to logic, memory to memory and memory to logic stacking in 3D in order to achieve the ultimate function integration densities.

As the processor power continues to escalate, this 3D IC trend will inevitably escalate thermal management challenges involving processors, memories and/or other logic devices in the 3D stacks beyond 2.5D applications. This necessitates the development of new thermal management approaches covering direct-to-chip liquid cooling and new 3D IC structures to maximize the utilities of these new thermal management approaches to ensure the dies in 3D ICs operate at their optimum operating temperatures. These new approaches and structures should also allow more efficient cooling of 2.5D ICs. For both 2.5D ICs and 3D ICs, they translate to far more efficient processor-memory operations and huge energy savings, and allow ever-higher-power/performance processors to be integrated with HBM DRAM stacks in close proximity for high-end HPC, data center and AI applications as the growth of data traffic continues to accelerate and as processor powers continue to increase.

### SUMMARY

It is one aspect of the present disclosure to provide a semiconductor package, including a first die having a front side and a backside, a substrate carrying the first die with the substrate comprising a first cavity allowing a liquid to pass through, and a cold plate over the first die with the cold plate having a second cavity configured to connect to the first cavity and allowing the liquid to flow between the first cavity and the second cavity.

It is another aspect of the present disclosure to provide a semiconductor package, including a processor die having a front side and a back side, a plurality of memory dies and control dies stacked over the processor die, a substrate carrying the processor die, the memory dies, and the control dies with the substrate having a first cavity allowing a liquid to pass through, and a cold plate over the processor die, the memory dies, and the control dies with the cold plate having a second cavity configured to connect to the first cavity and allowing the liquid to flow between the first cavity and the second cavity. The cold plate is in direct thermal contact with the processor die, a top die of the memory dies or the control dies.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 shows widening processor peak compute versus memory bandwidth gap.

FIG. 2 shows an evolution of processor chip power at data centers from 2018 to 2023.

FIG. 3 illustrates near-memory computing and in-memory computing package structures.

FIG. 4 illustrates six liquid cooling structures of IC in a three-die 3D IC stack similar to what was shown in the journal article, Brunschwiler et al., Journal of Electronic Packaging, March 2016, Vol. 138, ASME.

FIG. 5 shows computed thermal gradients from temperature at fluid inlet (T_{fin}) to the maximum junction temperature (Tⱼₘₐₓ) for the six liquid cooling structures in FIG. 4 extracted from the journal article described in FIG. 4.

FIG. 6 illustrates a direct-to-chip water cooled 2.5D IC package structure with a backside power delivery network (BSPDN), according to some embodiments of the present disclosure.

FIG. 6′ illustrates an enlarged view of the bonding structure in FIG. 6, according to some embodiments of the present disclosure.

FIG. 6A illustrate an enlarged view of a sealing structure in the semiconductor package, according to some embodiments of the present disclosure.

FIG. 7 illustrates a direct-to-chip water cooled 3D IC package structure with a BSPDN, according to some embodiments of the present disclosure.

FIG. 8 illustrates a direct-to-chip water cooled 3D IC package structure with a BSPDN, according to some embodiments of the present disclosure.

FIG. 9 illustrates a direct-to-chip water cooled 3D IC package structure with a BSPDN, according to some embodiments of the present disclosure.

FIG. 10 illustrates a direct-to-chip water cooled 3D IC package structure with a BSPDN, according to some embodiments of the present disclosure.

FIG. 11 illustrates a direct-to-chip water cooled 3D IC package structure with a BSPDN, according to some embodiments of the present disclosure.

FIG. 12 illustrates a direct-to-chip water cooled 2.5D IC package structure with a front side power delivery network (FSPDN), according to some embodiments of the present disclosure.

FIG. 13 illustrates a direct-to-chip water cooled 3D IC package structure with a FSPDN, according to some embodiments of the present disclosure.

FIG. 14 illustrates a direct-to-chip water cooled 3D IC package structure with a FSPDN, according to some embodiments of the present disclosure.

FIG. 15 illustrates a direct-to-chip water cooled 3D IC package structure with a FSPDN, according to some embodiments of the present disclosure.

FIG. 16 illustrates a direct-to-chip water cooled 3D IC package structure with a FSPDN, according to some embodiments of the present disclosure.

FIG. 17 illustrates a direct-to-chip water cooled 3D IC package structure with a FSPDN, according to some embodiments of the present disclosure.

FIG. 18 illustrates advanced interposers or ICs that can be created by a full sized, reconstituted diamond wafer, according to some embodiments of the present disclosure.

FIG. 19 illustrates advanced ICs that can be created by a full-sized reconstituted diamond-based bi-wafer, according to some embodiments of the present disclosure.

FIG. 20 illustrates advanced ICs that can be created by a full-sized reconstituted diamond-based tri-wafer, according to some embodiments of the present disclosure.

FIG. 21A to FIG. 21C provides manufacturing operations to form a processor-diamond combo with a BSPDN, according to some embodiments of the present disclosure.

FIG. 22 provides manufacturing operations to form a thermal isolation layer and a thermal spreading layer in interconnect layers or adjacent to an active region, according to some embodiments of the present disclosure.

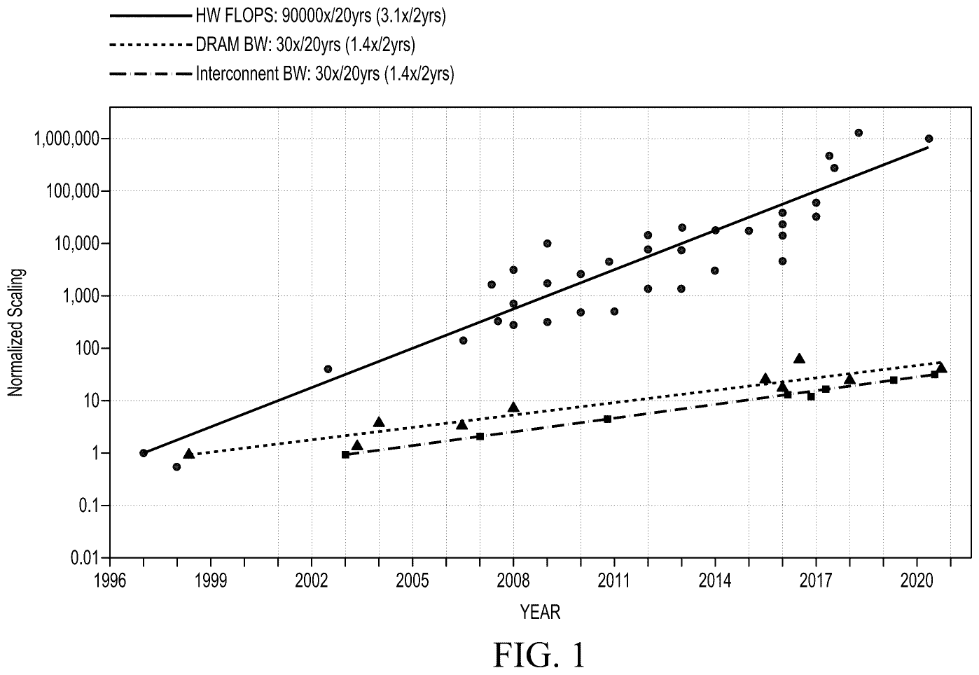

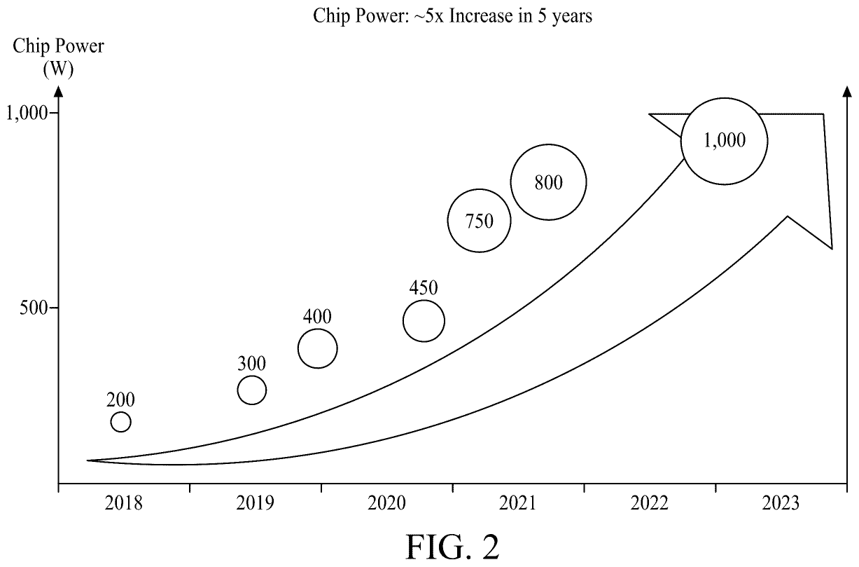

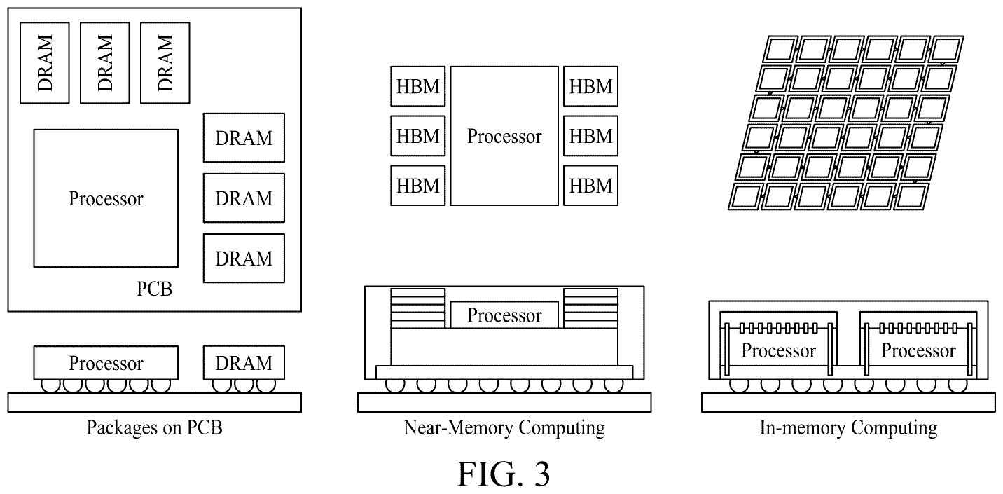

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

For traditional packaging, electrical interconnects for power supply and signaling go through the front-side (i.e., the side of the die that is bonded to the substrate) of the die while heat is removed from the backside of the chip. This applies to 2D flip chip and 2.5D integration of processors and 3D HBM DRAM stacks. This single-sided power and heat dissipation topology is invariant to the number of dies stacked in 3D and as a result is not scalable as the number of dies increases in the 3D stack.

Novel scalable packaging solutions is needed for 3D stacking to enable dual-sided cooling and even dual-sided electrical interconnection. These solutions can be expanded to covering 2.5D packaging solutions and future high-power devices with multiple and increasing numbers of tiers in the package thickness direction such as processors, cache, DRAM and accelerators for applications such as HPC, data centers, AI, 5G/6G/RF and even power semiconductors.

Today, air cooling is still the norm for the most part at data centers and many enhanced cooling methodologies (e.g., calibrated vectored cooling, cold aisle/hot aisle containment, computer room air conditioner, etc.) are being implemented to enhance the efficiencies of air cooling. These improvements tend to be offset, however, by the ever-increasing processor power and amounts of compute and storage required to satisfy the insatiable demands of consumers for more data. Although air cooling technology has improved significantly in the recent past, it suffers from significant energy costs at large data centers requiring introduction of moisture into sealed environments, and fixes of frequent mechanical failures associated with fans. To cope with the escalating data traffic, data centers are starting to experiment on and bring in liquid cooling technologies such as direct-to-chip liquid cooling and liquid immersion cooling which have been demonstrated to provide increased efficiency and effectively in cooling. Compared to air cooling systems which require a lot of power and bring with them pollutants and condensation into the data centers, liquid cooling systems can require less energy and lower operating cost, be cleaner, be more scalable, and be less dependent on climate and location.

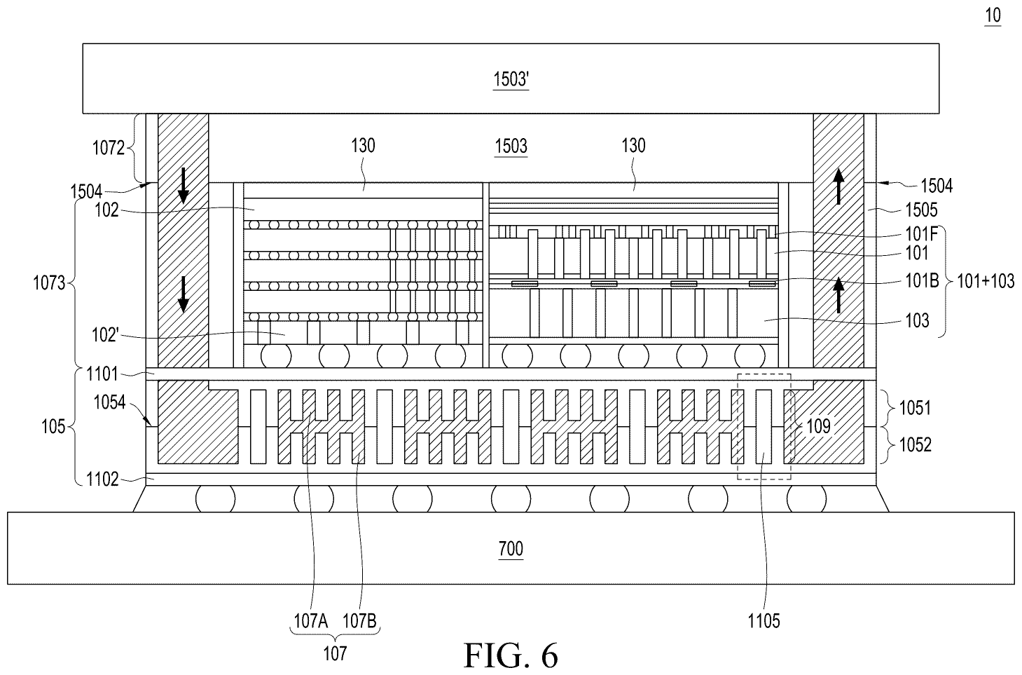

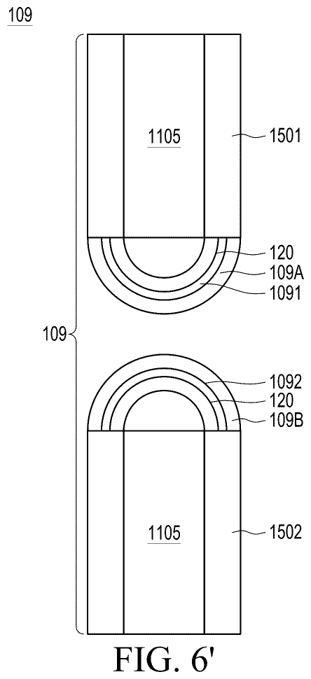

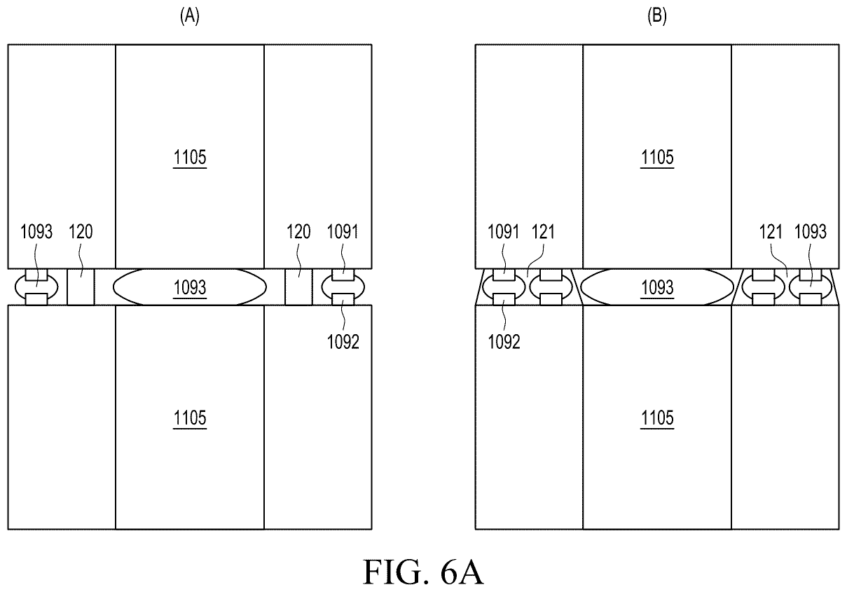

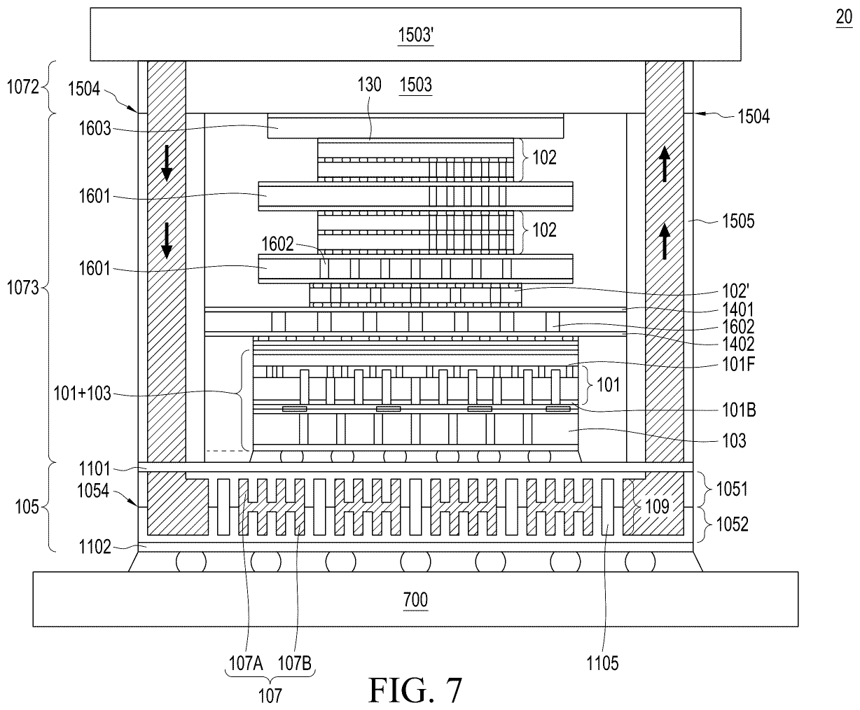

In some embodiments, the present disclosure provides semiconductor packages that (1) enable dual-side cooling from both the top side and bottom side of 2.5D IC and 3D IC structures (and other SiPs using 2.5D and 3D ICs for demonstration purposes here); and (2) contain fluidic micro-channels in the cold plate, the structural member, and the interposer. In some other embodiments, the present disclosure further provides semiconductor packages that enable enhanced cooling for front side power delivery network (FSPDN) structure or backside power delivery network (BSPDN) structure with respect to the active dies with processors in particular. In some other embodiments, the present disclosure further provides semiconductor packages that enable skip-die signal and power distribution, that is, power and signal can now be supplied from the bottom die or the interposer supporting the bottom die to not just the die directly above but also directly to all other dies in the die stack, and semiconductor packages that enable signal and power distribution from not only the front-side but also from the backside of the 3D IC stack. In some other embodiments, the present disclosure further provides semiconductor packages that enable power and signal delivery to a front side (i.e., the global interconnect side, see FIG. 6 or FIG. 7) of an active die (e.g., a processor) with a BSPDN structure.

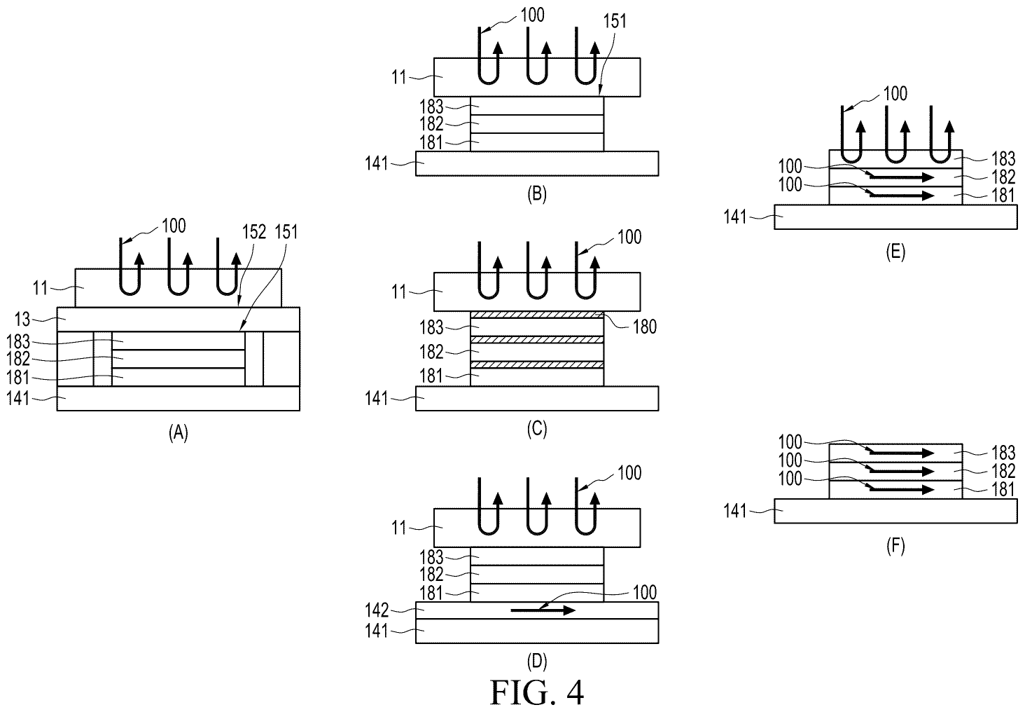

As previously described, for 2.5D or 3D IC thermal management involving high-end processor and memory, traditional air cooling is giving way to liquid cooling as processor powers soar. FIG. 4 shows six liquid cooling structures of IC using a three-die 3D IC stack for demonstration purpose only. Structure (A) is the current state-of-the-art structure with a liquid cooler 11 (e.g., a cold plate), which is cooled by direct contact with liquid coolant 100 and is disposed on a heat spreader 13 (e.g., a lid). The liquid cooler 11 can be a bolt-on cooler which requires a first thermal interface material (TIM) 151 for thermal coupling between the dies, 183, 182 and 181, and the heat spreader 13, and a second TIM 152 for thermal coupling between the heat spreader 13 and the liquid cooler 11. Structure (B) allows the liquid cooler 11, and thus the liquid coolant 100, to be close to the dies 183, 182, 181 (or die stack hereinafter) with the use of only one TIM 151 for thermal coupling between the dies, 183, 182 and 181, and the liquid cooler 11. Structure (C) is similar to structure (B) except for additionally implementing high thermal conductivity (HTC) components 180, e.g., a HTC TIM and/or a HTC heat spreading layer composed of diamond, graphene, boron nitride, boron arsenide, cubic boron arsenide, aluminum nitride, silicon carbide, or a combination thereof, in a bi-wafers and/or tri-wafer forms in the die stack. Structure (D) is similar to structure (B) except for additionally implementing an interposer 142 containing built-in fluidic micro-channels in the interposer 142 which is configured to support the die stack. Other structures may include a laminate substrate, PCB, and/or other suitable carriers 141 without built-in fluidic micro-channels. Structure (E) allows the liquid coolant 100 to directly access the top die 183 through the backside of the top die 183 without needing the TIM 151 thermally interfacing the dies 183, 182, 181 and the liquid cooler 11, and with fluidic micro-channels built into the bottom two dies, 181 and 182, and with the top die 183 serving as the cold plate. Structure (F) allows the liquid coolant 100 to flow within fluidic micro-channels embedded in all of the dies, 183,182 and 181. The biggest challenge regarding structure (E) and Structure (F) is they require co-optimization and co-processing of the thermal management structure/hardware with high-end, costly, and often thin processors and 3D IC stacks. Thin processors imply smaller cavities that can be created within and less efficient liquid cooling.

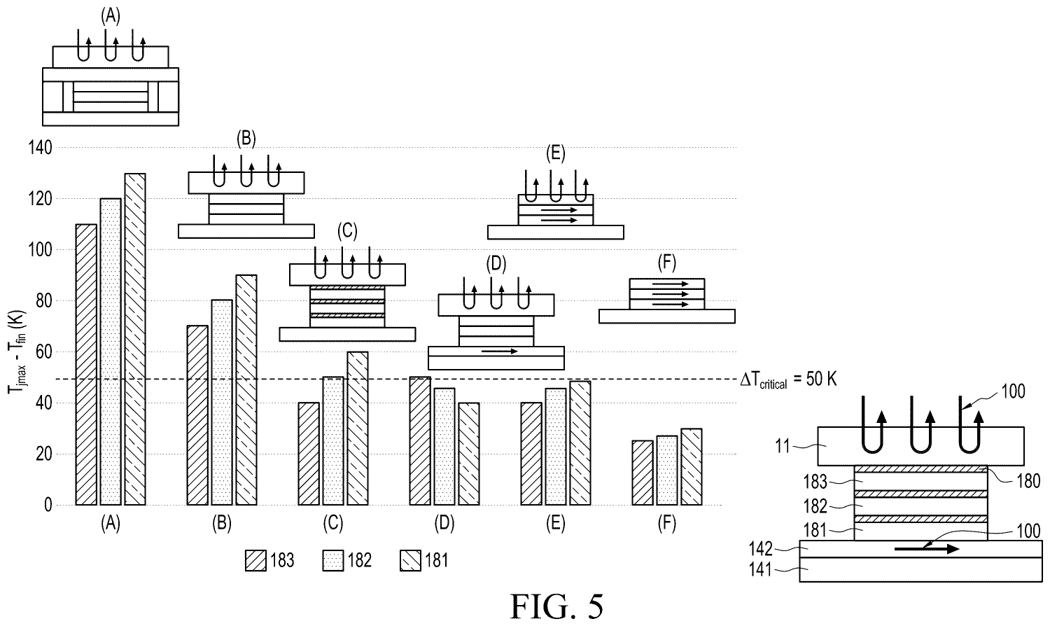

As shown in FIG. 5 (the experimental data are cited from Brunschwiler et al., Journal of Electronic Packaging, March 2016, Vol. 138, ASME), computed thermal gradients from temperature at fluid inlet (T_{fin}) to the maximum junction temperature (Tⱼₘₐₓ) for every die in the three-die stack (assuming the top die 183 is a microprocessor, the middle die 182 is a memory cache, and the bottom die 181 is an accelerator) indicates that cooling performance improves in the following order: from structure (A) to (B) to (C) to (D) and (E), and then to (F), where ΔT_{critical} represents the cooling thermal budget of 50° C. The performance of structure (D) approximates that of structure (E), with structure (E) involving complex IC fabrication challenges (e.g., cost, quality, reliability, time-to-market, etc.). For structure (D), the temperature of the top die 183 just met the 50° C. ΔT_{critical} requirement. As illustrated on the right of FIG. 5, combination of structure (C) and structure (D) that do not require creation of fluidic micro-channels in active ICs can be anticipated to exceed the performance of structure (E) and may approach that of structure (E) or structure (F) with the use of a proper heat spreading structure, a coolant and related flow patterns.

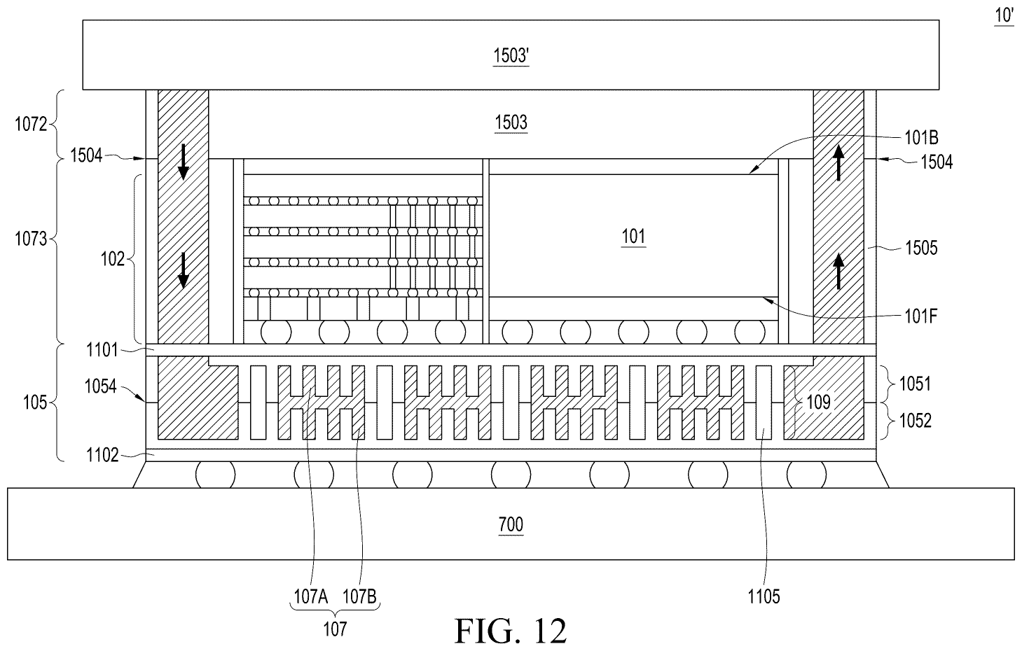

The embodiments utilizing the combination of structure (C) and structure (D) are demonstrated in FIG. 6 to FIG. 17, showing direct-chip liquid cooled semiconductor package structures with a backside power delivery network (BSPDN) (e.g., FIG. 6 to FIG. 11) or with a front side power delivery network (FSPDN) (e.g., FIG. 12 to FIG. 17). Though not the focus herein, similar structures without the interposers containing fluidic micro-channels can also find utilities in liquid immersion cooling.

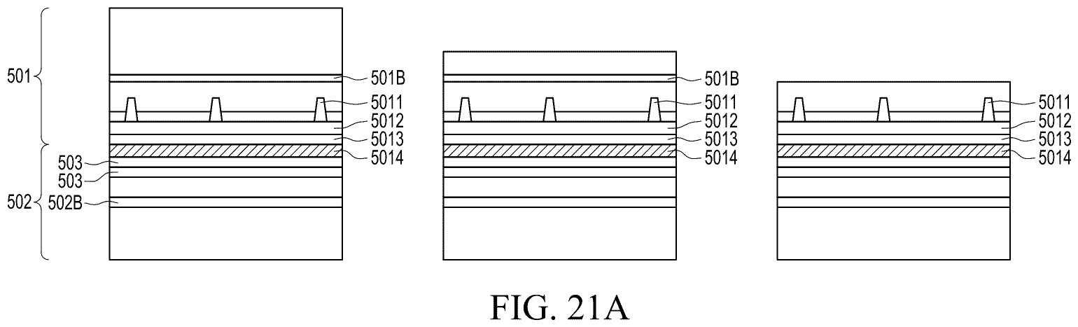

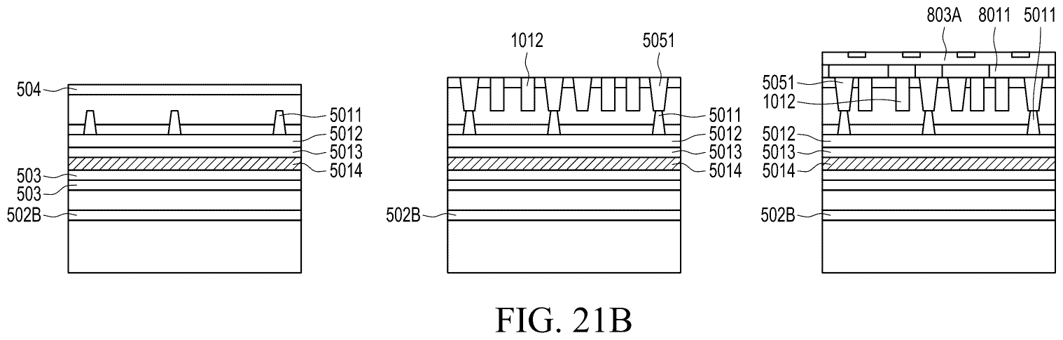

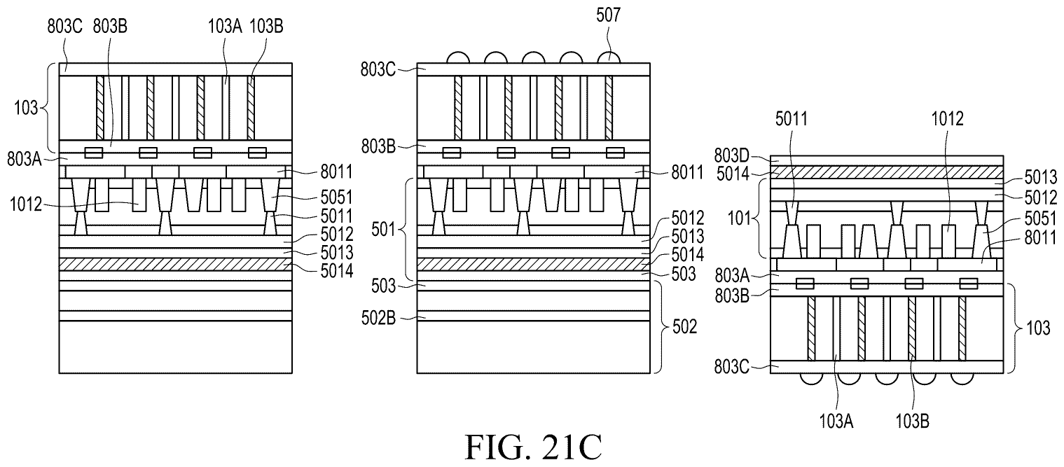

Referring to FIG. 6, the semiconductor package 10 includes a die 101, such as a processor die 101 referred herein, with a front side 101F and a backside 101B opposite to the front side 101F. As shown in FIG. 6, the backside 101B of the processor die 101 is facing downward and connected to a supporter 103 electrically and thermally coupled to the processor die 101. The processor die 101 is manufactured to have a backside power delivery network (BSPDN) with the backside 101B of the processor die 101 located in close proximity to the supporter 103 whereas the front side 101F of the processor die 101 is farther away from the supporter 103 compared to the backside 101B. One of the key technologies to enable scaling of future chips below 3 nm and the migration from finFET to nano-sheet transistors is BSPDN that allows designers to decouple the power delivery network from the signal network on the IC front-side, which is the side proximal to the FEOL (Front-end-of-line) 5012 (front-end-of-line), and the two BEOL (backend-of-line) layers, i.e., the local interconnect 5013, and the intermediate interconnect 5014 as further enlarged and illustrated in FIG. 21C. For future advanced ICs, the advantages of BSPDN include enhanced signal integrity, reduced IR drop, improved power delivery performance, reduced BEOL routing congestion, as well as further standard cell scaling. An ideal BSPDN has to deliver constant, stable supply voltage to active circuits on the IC during any activity. A key parameter here is the DC resistance of the power delivery network in all the interconnect paths, from the IC's power supply pins to the transistors in the IC. Detailed manufacturing operations and related structures of BSPDN in the processor die 101 and their connection to the supporter 103 can be referred to FIGS. 21A to 21C of the present disclosure.

The semiconductor package 10 further includes a substrate 105 supporting the combination of the processor die 101 with a BSPDN and the supporter 103 (or a “HTC-silicon combo” referred herein) or the processor die 101 with a FSPDN. The substrate 105 includes a cavity 107 in a form such as fluidic vias or fluidic micro-channels, allowing a liquid coolant to pass through during operation of the semiconductor package 10 to take the heat away. The substrate 105 can be made of silicon or other suitable materials that are amenable to microfabrication. In some embodiments, the substrate 105 may be an interposer substrate containing fluidic micro-channels that enables heat dissipation to take place from the backside 101B of the processor die 101 in the case of BSPDN or the front side (i.e., the FEOL side) of the processor die 101 in the case of FSPDN. The substrate 105 or the interposer substrate can be of a dual-shell construction (or multi-shell construction for larger cavities) with two interposer shells separately constructed and bonded together to increase (e.g., double) the heights and spaces of the cavity 107 and fluidic micro-channels created therein for enhanced cooling efficiencies. In some embodiments, the dual-shell construction of the substrate 105 includes two different parts, such as an upper portion 1051 which defines a first part 107A of the cavity 107 and a lower portion 1052 which defines a second part 107B of the cavity 107. The upper portion 1051 and the lower portion 1052 can be combined to form sealed fluidic micro-channels which permit the liquid coolant to circulate therein. In some embodiments, the upper portion 1051 and the lower portion 1052 can be bonded with a bonding structure 109 enlarged and shown in FIG. 6′. In some embodiments, a joint boundary 1054 can be observed at the interface of the upper portion 1051 and the lower portion 1052 of the substrate 105. In some embodiments, the bonding structure 109 may include a sealing structure 1091 located on the surface 109A of the upper portion 1051 and a matching sealing structure 1092 located on the surface 109B of the lower portion 1052 of the substrate 105. The substrate 105 may further include an interconnect or RDL layer 1101 facing the processor die 101 and an interconnect layer 1102 facing away from the processor die 101, and a through via 1105 electrically, optically, or thermally coupling the first interconnect layer 1101 and the second interconnect layer 1102. All through vias 1105 are embedded in and are protected by the substrate 105 material, e.g., silicon or other suitable materials.

Bonding of the dual-shell construction with two interposer shells can be achieved through a multiplicity of sealing structures with each pair of sealing structures consisting of a bottom portion and a matching top portion mimicking flip chip bonding structures (e.g., solder on the top seal ring and matching bottom seal ring with proper surface metallurgy to facilitate wetting of molten solder) with the use of a non-conductive paste/film as warranted for passivation as in micro-bump based flip chip assembly. Specifically, the sealing structures, 1091 and 1092, can be a pair of contact pads with a ring shape or with any other suitable closed geometries configured to receive bonding materials such as a solder. The sealing structure 1091 may geometrically match the shape of the sealing structure 1092. FIG. 6A shows a cross sectional view of the sealing structures, 1091 and 1092, (e.g., the sealing structures can be multiple seal rings), and the through via 1105. A bonding material 1093 can be positioned between the sealing structures, 1091 and 1092, and between the two mating through vias 1105 of the upper portion 1051 and the lower portion 1052 of the substrate 105 so as to bond the upper portion 1051 and the lower portion 1052 of the substrate 105 and define the cavity 107. Optionally, as shown in (A) of FIG. 6A, an additional isolation structure 120 can be placed between the through via 1105 and the bonding material 1093. With the isolation structure 120 forming a barricade between the bonding material 1093 and the through via 1105, which may be electrically (or optically) conductive, the bonding material 1093 can be isolated from the through via 1105 to prevent electrical short. In some embodiments, as shown in (A) of FIG. 6A, the multiple sealing structures, 1091 and 1092, can be replaced by a single large sealing structure extending from the innermost sealing structure all the way to the edge of the through via 1105 to achieve hermetic sealing against the liquid coolant. Similar to the isolation structure 120 previously described in (B) of FIG. 6A, with the use of a non-conductive paste/film 121 as warranted as in micro-bump based flip chip assembly, the bonding material 1093 can be isolated from the through via 1105 to prevent electrical short. Flip chip bonding of the upper portion 1051 and the lower portion 1052 of the substrate 105 can also be done in conjunction with a solder dam as warranted. Furthermore, the mating surfaces in close proximity of the through vias 1105 can contain protrusion and recessed style mating surfaces and connections to further isolate the through vias from the liquid coolant. Moreover, bonding of the sealing structures, 1091 and 1092, can also be achieved by copper hybrid bonding when copper is used as the conductive via material and a suitable dielectric material such as silicon dioxide is used.

Referring back to FIG. 6, the semiconductor package 10 further includes a cold plate 1503 and a structural member 1505 over the processor die 101. The cold plate 1503 may include a cavity 1072 and the structural member 1505 may include a cavity 1073, both configured to connect to the cavity 107 in the substrate 105, thereby allowing the liquid coolant to flow through the cavities, 107, 1072 and 1073. Although the cavity 1072 illustrated in FIG. 6 has a vertical portion vertically traversing the cold plate 1503, the shapes and forms of the cavity 1072 may vary as needed, for example, the cavity 1072 in the cold plate 1503 may include fluidic micro-channels in the bulk of the cold plate 1503. In some embodiments, the cold plate 1503 can be a manifold integrated cold plate, a planar heatsink, a fin-type heat sink, a vapor chamber, or a combination thereof, with the cold plate fluidly coupled to a heat exchanger integrated with the cold plate or away from the semiconductor package, and the structural member 1505

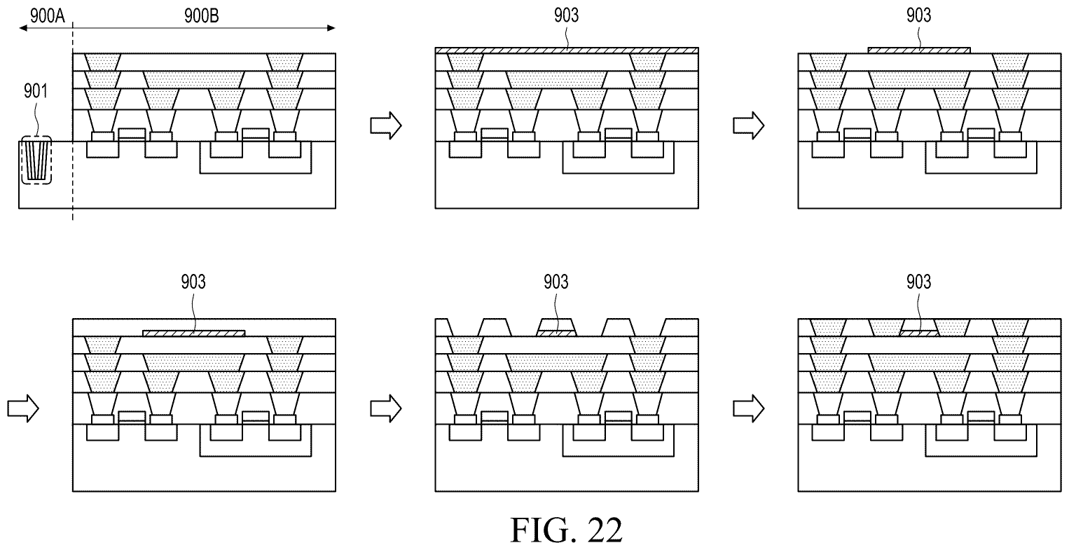

In FIG. 6, the semiconductor package 10 further includes multiple dies 102, or a plurality of memory dies 102 referred herein (e.g., HBM DRAM die stacks containing control ICs), mounted side-by-side with the processor die 101 on the supporter 103 over the substrate 105. The memory dies 102 or the HBM DRAM die stacks can be interconnected through micro-bumps or copper hybrid bonding. When micro-bumps are used, a non-conductive paste/film can be used to fill the interstices between two flip chip bonded components. Also, in order to go finer pitches, micro-bumps, particularly those between two ICs, can be replaced by copper hybrid bonds. The 2.5D IC (and 3D IC below) structures disclosed herein can be molded with the backside of the chips exposed for bonding to the cold plate through a TIM and to strengthen the structural integrity of the 2.5D IC (and 3D IC below) structures. A control die 102′ can be disposed between the memory dies 102 and the substrate 105. In some embodiments, a heat spreading layer or a thermal isolation layer can be disposed in the interconnect (on both the front side and backside) of the processor die 101, in the interconnects (both sides) of the supporter 103, in the interconnects (on both the front side and backside) of each of the memory dies 102 to facilitate heat isolation or heat spreading. Detailed structure and manufacturing operations of the heat spreading layer and the thermal isolation layer can be referred to FIG. 22 of the present disclosure. As shown in FIG. 6, the cold plate 1503 is in direct thermal contact with the top die of the memory dies 102 as well as the processor die 101 through a thermal interlayer material (TIM). One or more structural members 1505 are disposed side-by-side with the processor die 101 on the supporter 103 and the memory dies 102. Any one of the structural members 1505 may possess a cavity 1073 machined to connect with the cavity 107 and the cavity 1072, allowing the liquid coolant to flow interchangeably between the cavities, 107, 1072 and 1073. The cold plate 1503 and structural members 1505 can be made of copper, silicon or other HTC materials such as diamond. In the cases of silicon, the cold plate 1503 and structural members 1505 can be machined and created using MEMS, wafer BEOL and advanced packaging processes and materials. In some embodiments, since the cold plate 1503 and the structural members 1505 can be separately manufactured and assembled in subsequent operations, a joint 1504 can be observed at the boundary of the cold plate 1503 and the one or more structural members 1505. This joint can be formed using bonding or welding.

As shown in FIG. 6, a thermal interlayer 130 is in direct physical contact with the cold plate 1503 and the top die of the memory dies 102 as well as the processor die 101. In some embodiments, the thermal interlayer 130 includes thermal interface materials (TIM s), diamond, graphene, boron nitride, boron arsenide, cubic boron arsenide, aluminum nitride, silicon carbide, copper-based material, or a combination thereof. The thermal interlayer 130 connecting the backside of the dies to the cold plate 1503 which, in turn, is connected to a manifold 1503′ can be proximal to or at a distance away from the semiconductor package 10. The thermal interlayer 130 allows for heat dissipation to take place from the front side 101F of the processor die 101 in the semiconductor package 10.

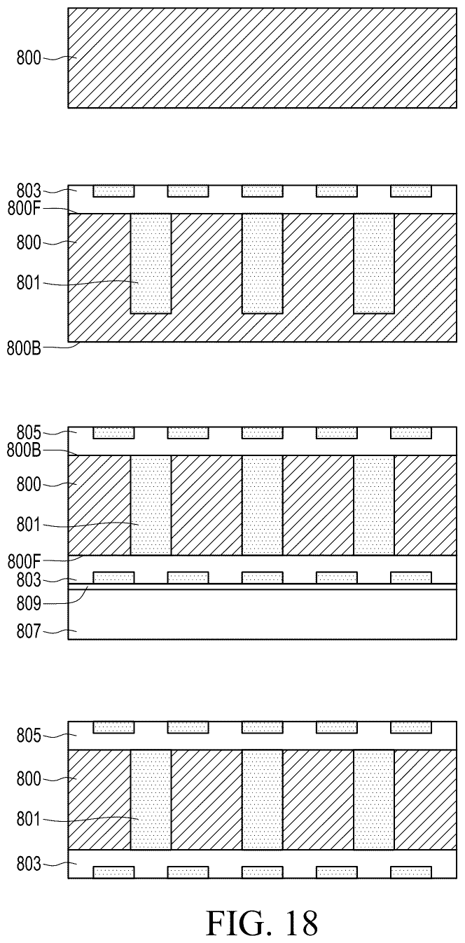

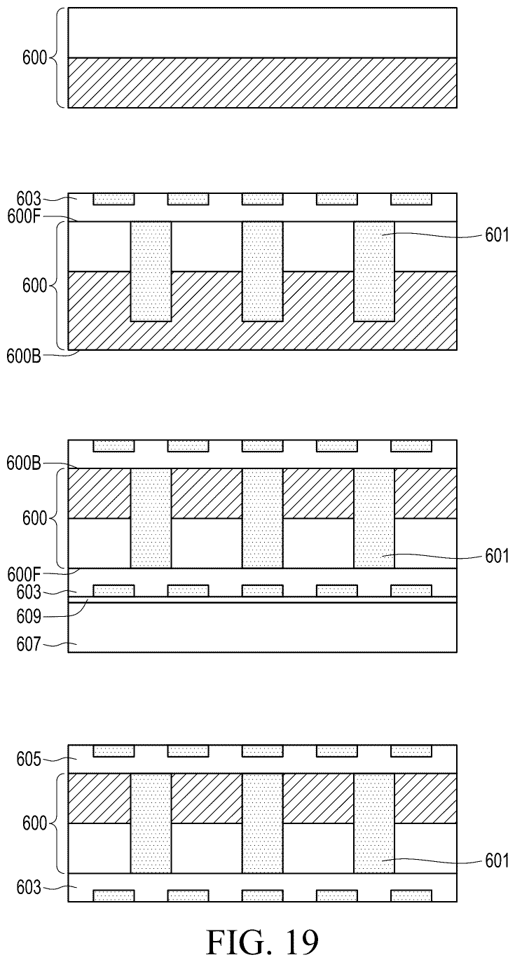

In FIG. 6, the supporter 103, or a high thermal conductivity (HTC) structure referred herein, disposed in between the processor die 101 and the substrate 105, thermally couple the two. The supporter can contain through vias 1105 and redistribution layer or layers (RDL) on both sides. In some embodiments, the thermal conductivity of the supporter 103 is greater than the thermal conductivity of the processor die 101. Material having a thermal conductivity greater than that of the semiconductor material used for die construction in the same semiconductor package is called a high thermal conductivity (HTC) material herein. In some embodiments, the HTC material described herein may include diamond, graphene, boron nitride, boron arsenide, cubic boron arsenide, aluminum nitride, silicon carbide, or a combination thereof, and the substrate is composed of silicon, diamond, graphene, boron nitride, boron arsenide, cubic boron arsenide, aluminum nitride, silicon carbide, or a combination thereof. The supporter 103 may include through vias 1105 (FIG. 6) to provide functions in addition to heat dissipation. For example, the through vias 1105 can be through-diamond vias (TDV), through-silicon-diamond-vias (TSDV) transmitting electrical, optical signals, and/or thermal vias to facilitate heat conduction. Detailed structure and manufacturing operations of a HTC interposer (e.g., a diamond interposer) can be referred to FIGS. 18, and 19 of the present disclosure.

In FIG. 6, the supporter 103 allows for heat dissipation to take place from the backside 101B of the processor die 101. The supporter 103 connecting the backside 101B of the processor die 101 to the substrate 105 having fluidic micro-channels that allows the liquid coolant injected to the fluidic micro-channels to effectively carry away the heat generated by the processor die 101. With the cold plate 1503 disposed over the front side 101F and the substrate 105 disposed at the backside 101B of the processor die 101, the heat generated by the processor die 101, for example, one or more high-end processors generating higher power (e.g., up to 700 W/chip for GPUs as in the case of nVidia H100 and 400 W/chip for CPUs), can be dissipated in dual directions, i.e., from the front side 101F and the backside 101B of the processor die 101 toward the cold plate 1503 and the substrate 105, respectively.

As shown in FIGS. 6 to 11, the supporter 103 and the processor die 101 forming a combo structure so that a cross sectional width of the processor die 101 and a cross sectional width of the supporter 103 are substantially identical. Detailed structures and manufacturing operations regarding the creations of BSPDN in the processor die 101 and its connection to the supporter 103 can be referred to FIGS. 21A to 21C of the present disclosure.

Referring to FIG. 7, FIG. 7 shows a semiconductor package 20 similar to the semiconductor package 10 with the exceptions that the semiconductor package 20 is a 3D IC structure with the memory dies 102 (e.g., the HBM dies) mounted directly on the processor die 101 which, in turn, is mounted on the substrate 105, and that one or more supporters 1601 (e.g., diamond interposers with RDL on both sides and TDVs) are disposed between the processor die 101 and the control IC 102′ underneath the memory dies, and between memory dies 102. As provided herein, memory dies 102 may also be referred to include one or more control ICs. Identical numerals shown in FIG. 7 and FIG. 6 refer to substantially identical or equivalent components as those previously provided in the semiconductor package 10 of FIG. 6, and are not repeated here for brevity. In FIG. 7, a supporter 1601, or a HTC structure referred herein, is disposed between the front side 101F of the processor die 101 and the control die 102′. As previously discussed, the supporter 1601 can be composed of materials similar to that of the supporter 103 in the package structure 10 and built with through vias 1602 similar to that of the supporter 103 in the package structure 10. In FIG. 7, the supporter 1601 includes interconnects at both sides, such as the redistribution layer (RDL) 1401 on a side facing away from the processor die 101 and the RDL 1402 on an opposite side facing the processor die 101. The through vias 1602 in the supporter 1601 electrically connect the RDL 1401 and the RDL 1402. As previously described in the semiconductor package 10, the heat spreading layer and/or the thermal isolation layer can be further disposed in the interconnects, i.e., the RDLs, 1401 and 1402, of the supporter 1601 to facilitate heat isolation or heat spreading.

As shown in FIG. 7, more supporters 1601 can be disposed between the control IC 102′ and one of the memory dies 102 and between memory dies 102. As provided herein, memory dies 102 may also be referred to include one or more control ICs. For example, the supporter 1601 can be disposed between the control die 102′ and the bottom die of the memory dies 102. The supporter 1601 can also be disposed between two of the adjacent memory dies 102. In some embodiments, since the supporters 1601 and any one of the memory dies 102 or processor die 101 are individually fabricated, a cross sectional width of the supporter 1601 and a cross sectional width of the dies 101 and/or 102 can be similar or different, for instance, the former can be greater than the latter. In addition, a HTC plate 1603 which can contain thermal vias but no electrical vias can be disposed between the top die of the memory dies 102 and the bottom of the cold plate 1503 using TIMs, a combination of a TIM and direct bonding or a combination of a TIM and glue layers so as to form direct thermal contact. With the cold plate 1503 disposed over the front side 101F and the substrate 105 disposed at the backside 101B of the processor die 101, the heat generated by the processor die 101, for example, one or more high-end processors generating higher power (e.g., up to 700 W/chip for GPUs as in the case of nVidia H100 and 400 W/chip for CPUs), can be dissipated in dual directions, i.e., from the front side 101F and the backside 101B of the processor die 101 mounted on the supporter 103 toward the cold plate 1503 and the substrate 105, respectively. Furthermore, the HTC supporters 1601 also enable heat dissipation to be enhanced upward through them.

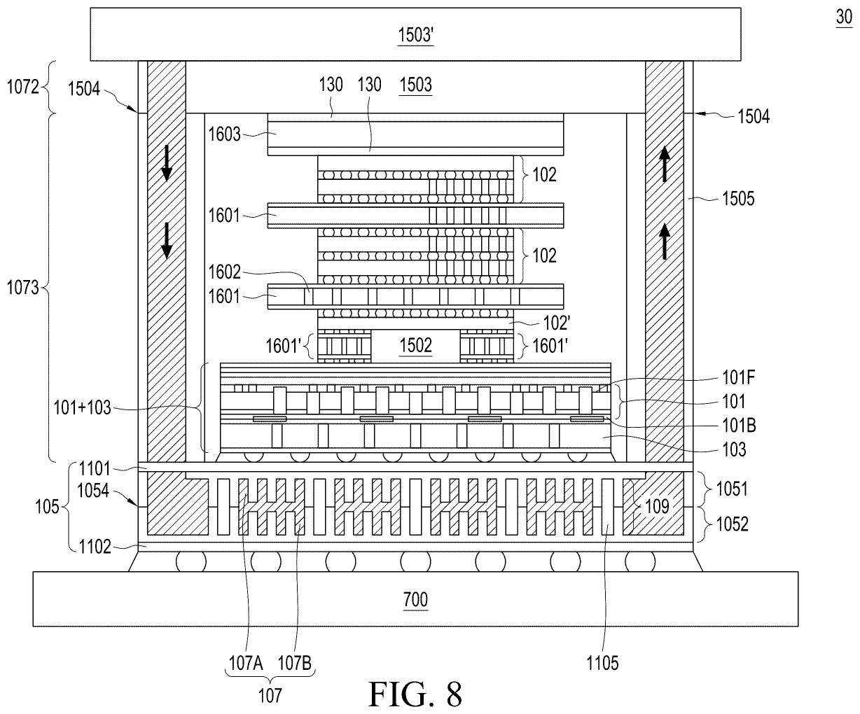

Referring to FIG. 8, FIG. 8 shows a semiconductor package 30 similar to the semiconductor package 20 with the exception that the semiconductor package 30 includes low-thermal-conductivity (LTC) spacer interconnects 1601′ (e.g., a silicon based interposer/spacer) in a particular arrangement that forms an air gap 1502 over the front side 101F of the processor die 101 with the LTC spacer interconnects 1601′ replacing the supporter 1601 made of HTC material in between the control IC and the processor, as shown in the semiconductor package 20. Identical numerals shown in FIG. 8 and FIG. 7 refer to substantially identical or equivalent components as those previously provided in the semiconductor package 20 of FIG. 7, and are not repeated here for brevity. In FIG. 8, the spacer interconnects 1601′ having a cross sectional width smaller than that of the processor die 101 and that of the control die 102′ form an air gap 1502 between the control die 102′ and the heat source of the processor die 101 over its front side 101F. Since the heat generated by the processor die 101, to some extent, is isolated from the control die 102′ by virtue of the air gap 1502 and the LTC spacer interconnects 1601′, the thermal budget to the control die 102′ may be lessened while at the same time, the heat from the processor die 101 can be dissipated downward through the supporter 103 under the processor die 101 that is thermally coupled to the substrate 105 containing fluidic micro-channels 107, the structural member 1505, the cold plate 1503 and the manifold. Alternatively, the LTC spacer interconnects 1601′ can be composed of HTC materials.

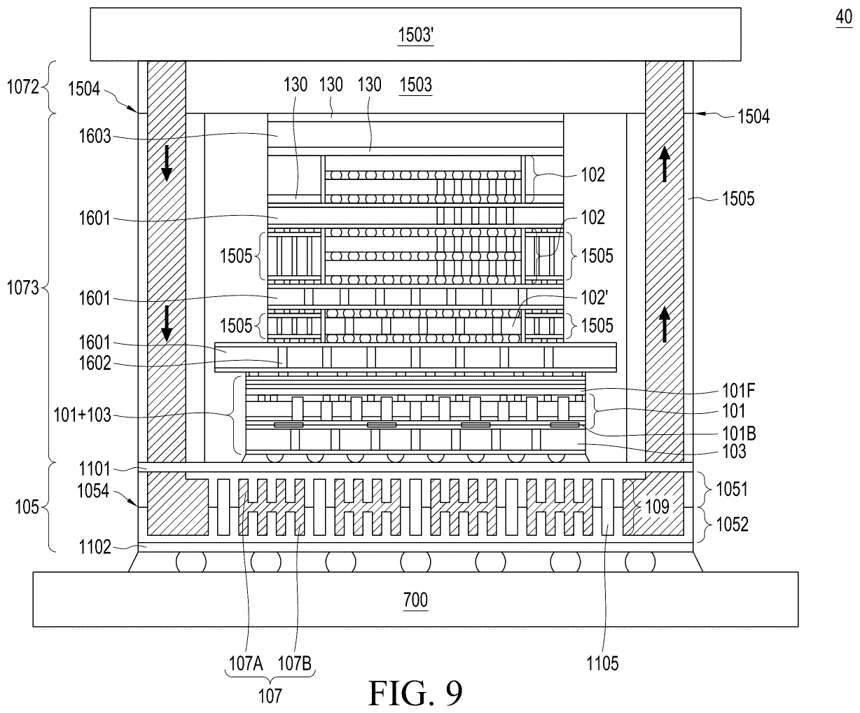

Referring to FIG. 9, FIG. 9 shows a semiconductor package 40 similar to the semiconductor package 30 with the exceptions that HTC spacer interconnects (or referred to as a second structural member 1505 herein) are used instead of LTC spacer interconnects 1601′ in FIG. 8, the HTC spacer interconnects or the second structural member 1505 do not form an air gap, and the control IC 102′ is placed between two supporters 1601 (e.g., diamond interposers), as previously described in FIGS. 7 and 8, in a vertical direction. The HTC spacer interconnects or the second structural members 1505 are also placed side-by-side with memory dies 102 covering control ICs. Although not shown in FIG. 9, the HTC spacer interconnects or the second structural member 1505 can be disposed side-by-side with the processor die 101 in some embodiments. Identical numerals shown in FIG. 9, FIG. 8 and FIG. 7 refer to substantially identical or equivalent components as those previously provided in the semiconductor package 30 of FIG. 8, and are not repeated here for brevity. First structural members 1505 which include a cavity 1073 and allow the liquid coolant to pass through as previously mentioned, are arranged side-by-side with the control die 102′ and the memory dies 102 atop the control die 102′. The supporters 1601 and the spacer interconnects 1505 enable skip-die and multi-sided power supply and signaling from the processor die 101 directly to the control die 102′ and any of the dies 102 above the control die 102′ as opposed to the traditional single-sided power supply and signaling. The (HTC) supporters 1601 and the HTC spacer interconnects or the second structural members 1505 also enable heat dissipation to proceed in dual directions, upward and downward and be enhanced upward through the (HTC) supporters 1601 and HTC spacer interconnects or the second structural members 1505

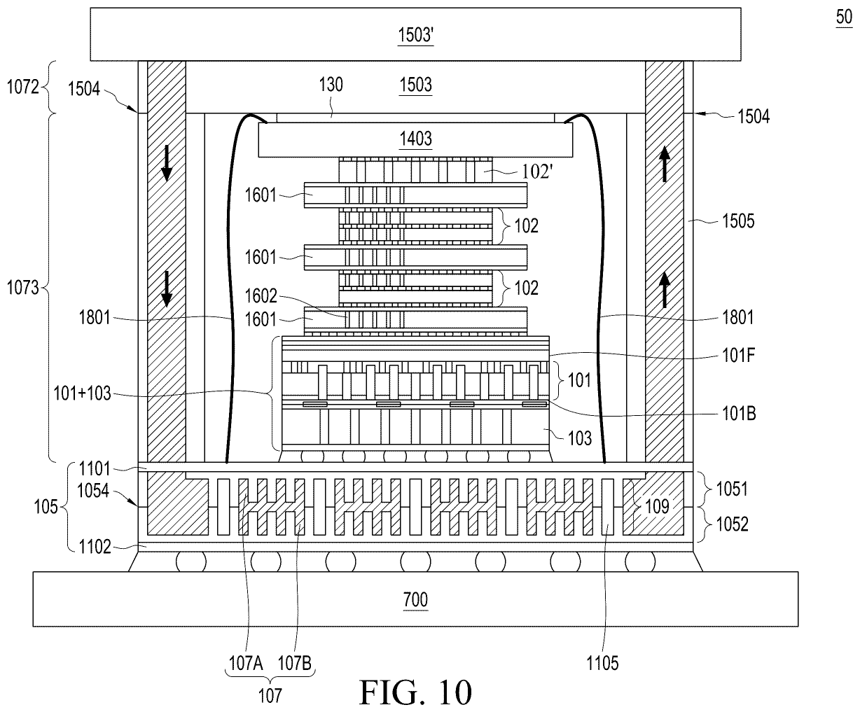

Referring to FIG. 10, FIG. 10 shows a semiconductor package 50 similar to the semiconductor package 20 with the exception that the semiconductor package 50 provides power supply and signaling to the back side 101B of the processor die 101 through the supporter 103 and the substrate 105, and also to the front side of the control die 102′, which is disposed on top of the HBM DRAM dies mounted on the processor die, through the use of a flexible circuit interconnect (Flex) 1801 which is interconnected to the substrate 105 or the electronic component (e.g., a laminate substrate 700 underlying the substrate 105). Identical numerals shown in FIG. 10 and FIG. 7 refer to substantially identical or equivalent components as those previously provided in the semiconductor package 20 of FIG. 7, and are not repeated here for brevity. The flex 1801 connects the substrate 105 or the component (e.g., a laminate substrate 700) underneath the substrate 105 to a circuit layer 1403 proximal to the cold plate 1503. In FIG. 10, power is delivered to the front side of the control die 102′ through the circuit layer 1403, which can be a low-coefficient of thermal expansion (CTE), HTC material such as a diamond or clad metal (e.g., copper-invar-copper) interposer. In some embodiments, the CTE of the circuit layer 1403 is matched to that of the control die 102′ (e.g., silicon) to enhance heat dissipation and reliability. In some other embodiments, as provided by the semiconductor package 50, the control die 102′ is disposed on top of the memory dies 102 instead of at the bottom of the memory dies 102 as previously shown in other semiconductor packages. The flexible circuit interconnect 1801 can be composed of polyimide and Cu interconnect similar to that found in driver IC packaging. The semiconductor package 50 allows for dual sided power and signaling, as well as dual-sided heat dissipation with enhanced upward heat dissipation with using the (HTC) supporters 1601.

Flexes 1801 based on polyimide dielectric with multiple, say, 2 metal (copper, Cu) layers can be good interconnect solutions for high-speed applications. Flexes can also be used for interconnecting metal pads not just on one side face but also metal pads on multiple side faces because Flexes are mechanically formable and bendable. Flexes can provide high-density interconnects (with pitches down to 20 μm and even to 10 μm), DC power distribution, integrated I/Os (inputs and outputs), power distribution, decoupling and electro-magnetic compatibility. All the above good attributes coupled with that Flexes can be tested known-good prior to bonding make Flexes (particularly, adhesive-less Flexes) ideal candidates for 3D interconnection. Take chip-on-film (COF) bonding for liquid crystal display applications for instance, adhesive-less Flexes with Cu leads (which can be pre-plated with tin, Sn) are bonded using thermo-compression bonding (TCB) to, for instance, gold bumps, Sn bumps or tin/copper (Sn/Cu) bumps on glass or the substrate for applications such as mobiles. A solvent-less epoxy based underfill can be applied following bonding to avoid air bubbles that can be associated with solvent based underfills if not baked properly. Alternatively, a non-conductive adhesive (NCA) or non-conductive paste (NCP) can be applied prior to bonding to glass followed by TCB, in a way similar to fine-pitch flip chip micro-bump assembly. Pre-baking the circuitry prior to Flex bonding can be performed to ensure delamination will not occur. Metal pads on bonded Flexes residing on different side faces can be interconnected using, for instance, Flexes with leads/pads containing palladium (Pd) passivation for Flex-to-Flex bonding at low-temperatures such as 140° C.

Clad metals such as copper-invar-copper and copper-Mo-copper possess unique properties to be used as the circuit layer 1403. Invar is a Fe—Ni alloy with a 36% nickel content that exhibits the lowest coefficient of thermal expansion (CTE) of known metals and alloys, at for example, 1.2 ppm/° C. between 20° C. and 100° C., and its CTE stays low from the lowest temperatures up to approximately 230° C. By adjusting the thicknesses of copper, core metal (Invar or Mo) and copper, one can get the clad metal's CTE to be close to that of silicon (about 3 ppm/° degree C.), or between that of silicon and PCB (about 12 ppm/° C.). An invar sheet having a thickness of between 0.5 mil and 5 mil, and a layer of electrodeposited copper on at least one side of a thickness between 1 μm and 50 μm has a CTE of 2.8 to 6 ppm 1° C. at a temperature between 0° F. and 200° F. In addition, one can adjust the thicknesses of the clad metal layers to achieve a HTC, say 2 to 3 W/cm·K (versus 4 W/cm·K for copper), which is much higher than that of silicon (1.5 W/cm·K).

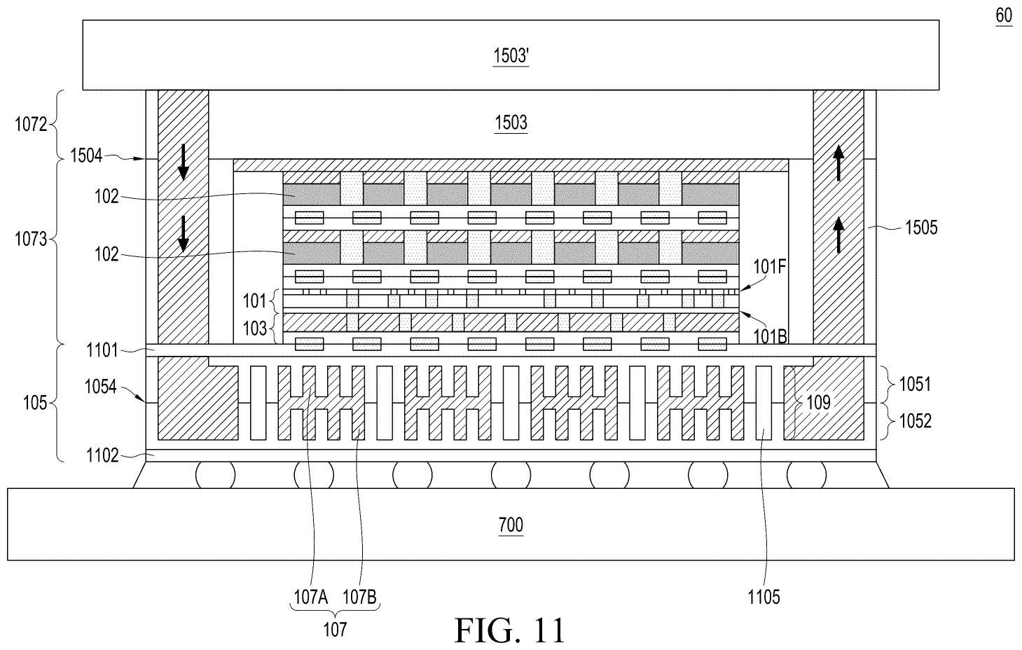

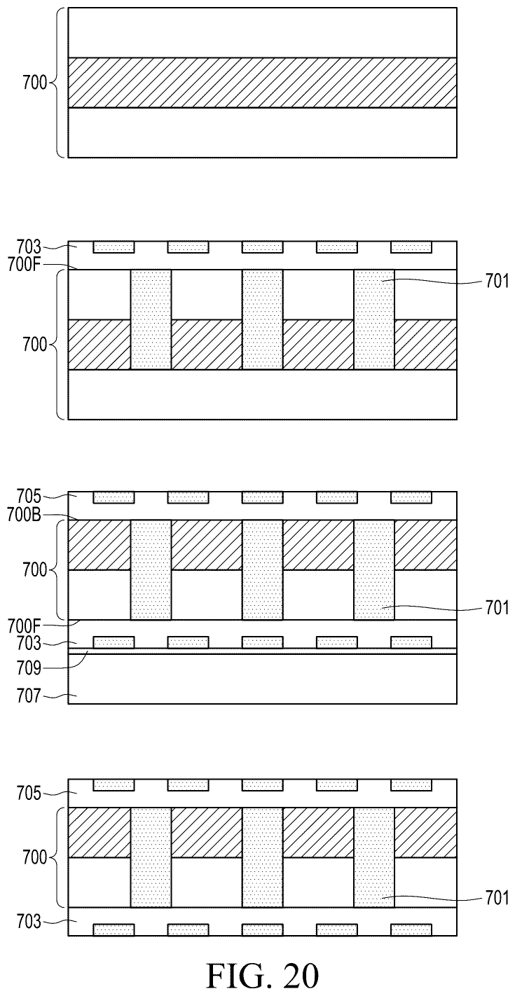

Referring to FIG. 11, FIG. 11 shows a semiconductor package 60 similar to the semiconductor package 20 except that the second die 102 and the third die 102 in the semiconductor package 60 are made up of HTC component such as a composite layer diced from a HTC-silicon composite wafer. Identical numerals shown in FIG. 11 and FIG. 7 refer to substantially identical or equivalent components as those previously provided in the semiconductor package 20 of FIG. 7, and are not repeated here for brevity. The HTC-silicon composite wafer, from which the composite layer in the semiconductor package is diced, can be made of, for instance, silicon-diamond bi-wafers or silicon-diamond-silicon tri-wafers. Detailed structures and manufacturing operations using the HTC-silicon composite wafers to form ICs and interposers can be referred to FIGS. 19 and 20 of the present disclosure.

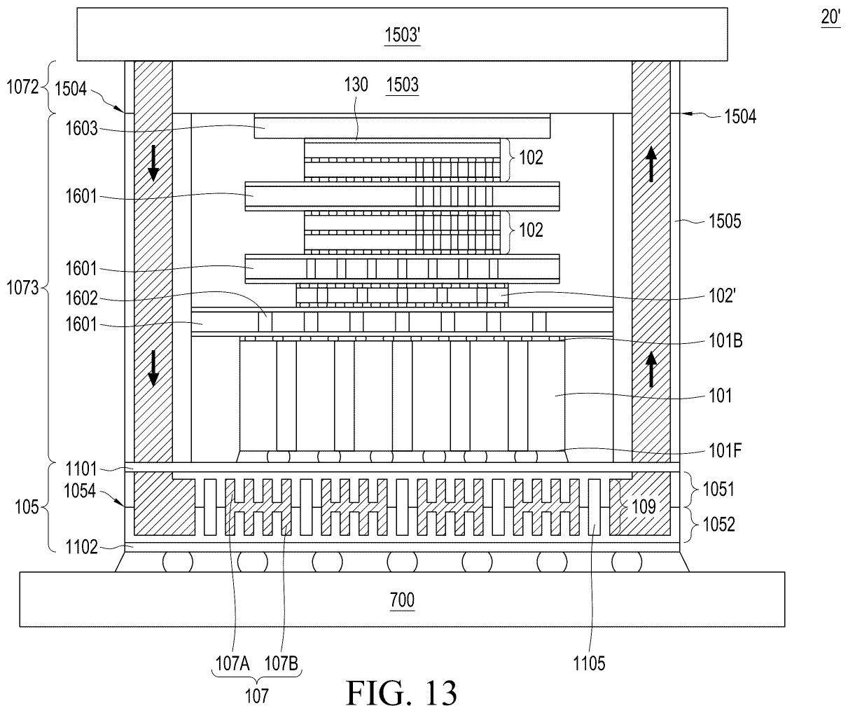

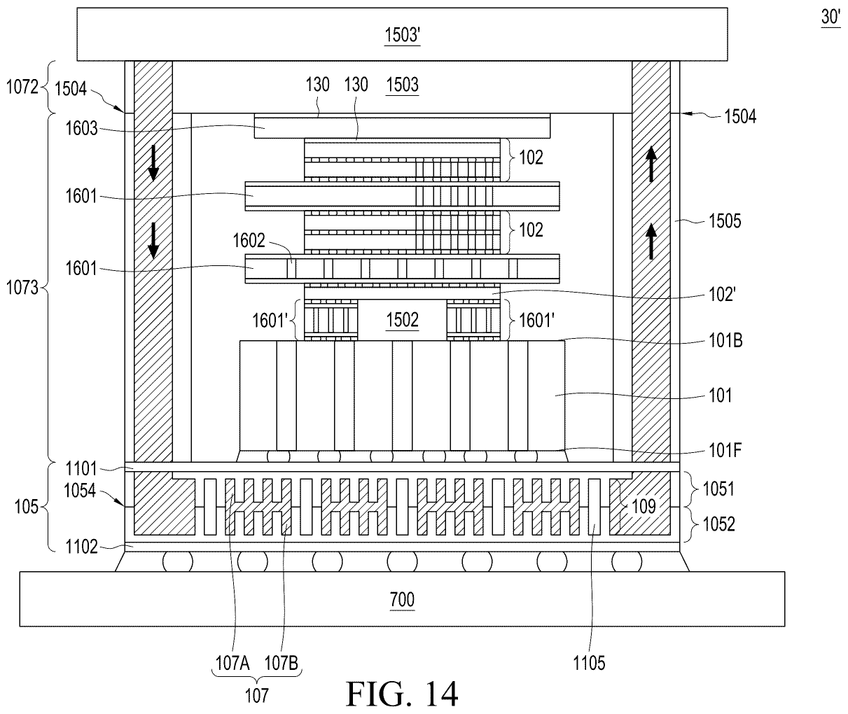

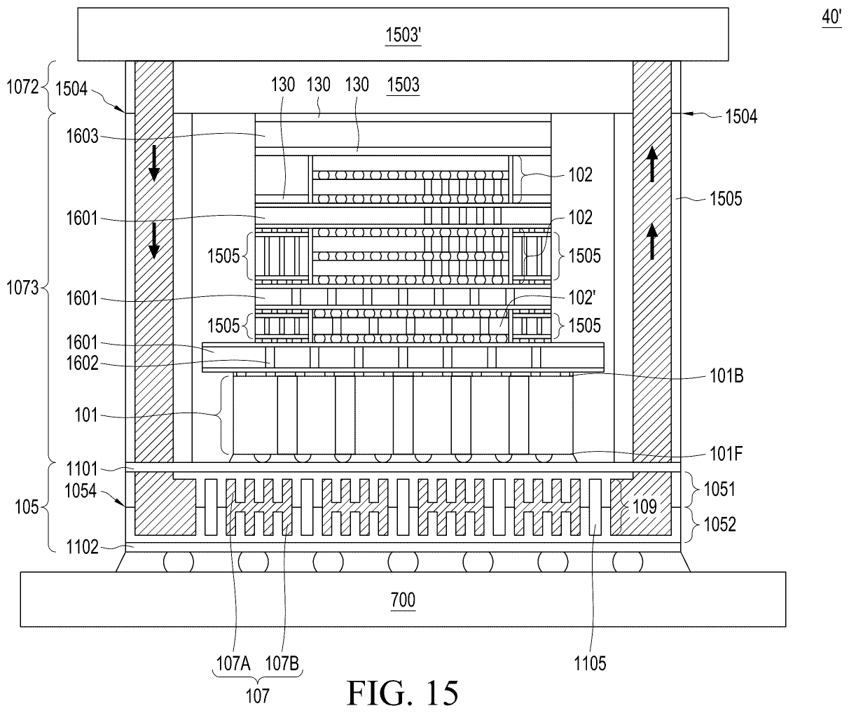

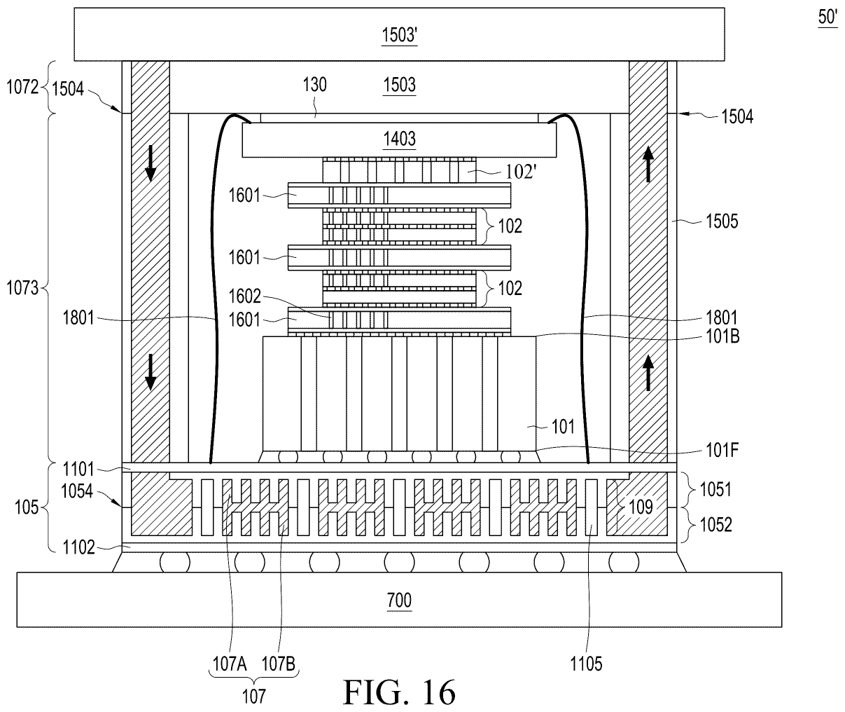

Semiconductor packages, 10′, 20′, 30′, 40′ and 50′, shown in FIGS. 12 to 16 are FSPDN counterparts of the semiconductor packages, 10, 20, 30, 40 and 50, respectively in FIGS. 6 to 10 based on BSPDN. In FIGS. 12 to 16, the processor dies 101 contain FSPDN formed on the front side (i.e., the FEOL/BEOL side) 101F of the processor dies 101 in the BEOL/FEOL layers. Identical numerals shown in FIG. 6, FIG. 7, FIG. 8, FIG. 9, FIG. 10 and FIG. 12, FIG. 13, FIG. 14, FIG. 15, FIG. 16 refer to substantially identical or equivalent components and are not repeated here for brevity. The processor die 101 having a FSPDN is packaged with its front side 101F facing the substrate 105 and a backside 101B facing the cold plate 1503 (see the 2.5D IC structure in FIG. 12) or the control die 102′ (see the 3D IC structures in FIG. 13, FIG. 14, FIG. 15, FIG. 16) and the memory dies 102 (e.g., in the HBM memory die stacks).

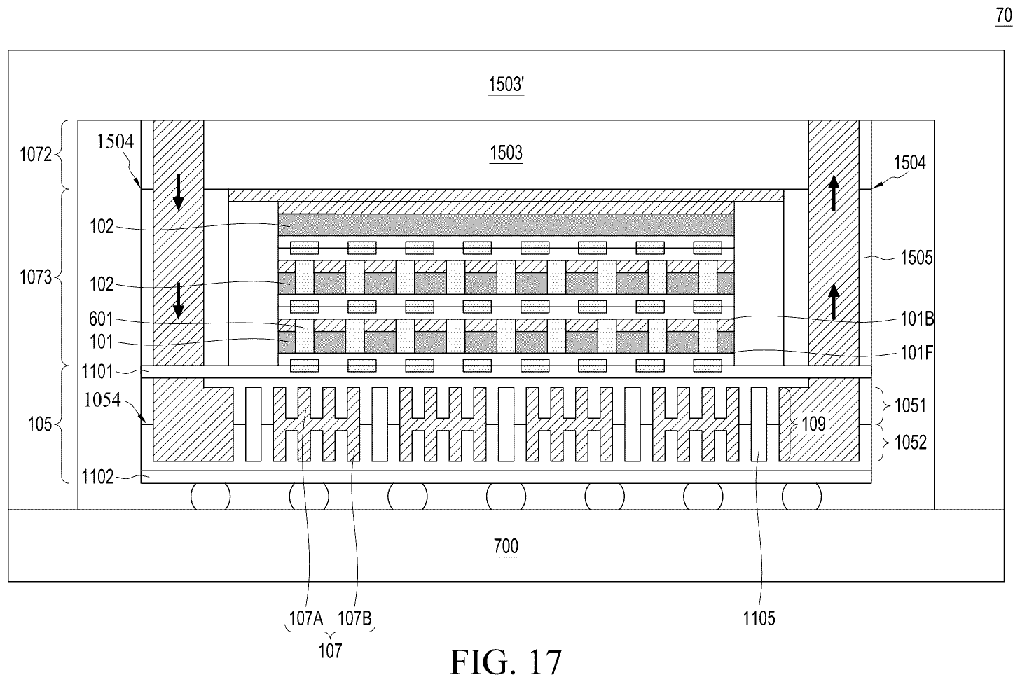

Referring to FIG. 17, FIG. 17 shows a semiconductor package 70 similar to the semiconductor package 60 in FIG. 11 except that in the semiconductor package 70, the processor die 101 with a FSPDN can be made of a HTC-silicon composite wafer using processes described in FIG. 19 and FIG. 20 instead of the processor-HTC combo as previously described under the BSPDN scheme. Identical numerals shown in FIG. 11 and FIG. 17 refer to substantially identical or equivalent components as those previously provided in the semiconductor package 60 of FIG. 11, and are not repeated here for brevity. Detailed structures and manufacturing operations regarding the use of HTC-silicon composite wafers (e.g., silicon-diamond bi-wafers or silicon-diamond-silicon tri-wafers) to form ICs and interposers can be referred to FIG. 19 and FIG. 20 of the present disclosure. The through-silicon-diamond vias (TSDV) 601 can be observed, for instance, in the HTC-silicon composite wafer which forms the processor die 101.

Although not illustrated in the semiconductor packages, 10′, 20′, 30′, 40′ and 50′, (shown in FIGS. 12 to 16) containing processor dies 101 with FSPDN, an additional supporter similar to the supporter 103 described herein can be optionally inserted between the front side 101F of the processor die 101 and the substrate 105. In some embodiments, a cross sectional width of the processor die 101 can be substantially identical to or smaller than a cross sectional width of the supporter optionally inserted between the front side 101F of the processor die 101. In order to better increase the thermal dissipation efficiency of the semiconductor packages described herein, one or more of the processor die 101 and the control dies and memory dies 102 may additionally possess built-in fluidic micro-channels which require co-optimization and co-processing of such thermal management features/structures with high-end IC fabrication processes.

FIG. 18 provides advanced interposers or ICs that can be created by diamond wafers. To create the diamond interposers from full-sized reconstituted diamond wafers, one can begin with a diamond substrate 800 (for instance, about 100 μm thick and approximate to a thickness of a 2.5D silicon interposer) and subject it to deep reactive ion etching (DRIE, or the so-called Bosch process) utilizing oxygen as the etch gas (along with other heavier gases such as CF₄) and a mask such as aluminum/silicon dioxide, aluminum/silicon/aluminum, or stainless steel to create high-aspect ratio through-diamond via (TDV) holes (not shown) at high etch rates. In some embodiments, thousands of the TDV holes with 20 μm in diameter at an aspect ratio of 5 are created per interposer after DRIE operation. Other mask choices that can be considered include aluminum, titanium, gold, chromium, silicon dioxide, aluminum oxide, photoresist and/or spin-on-glass. The etch mask material needs to be etched slower than diamond in DRIE with high selectivity. Ultra-short-pulse (e.g., femtosecond-pulsed) laser micromachining can also be used with etching and cleaning as needed, or in conjunction with the DRIE processes to create the TDV holes for improved etch performance. A combination of DRIE and epitaxial deposition can create ultra-high-aspect-ratio (up to 500) holes in silicon. It may also be fashioned after to create ultra-high-aspect-ratio TDVs. Following TDV hole opening, one may implement optionally plasma enhanced chemical vapor deposition (PECVD) of a dielectric such as silicon dioxide, and physical vapor deposition (PVD) of barrier/seed titanium/copper (Ti/Cu) or tantalum nitride/Cu (TaN/Cu) by sputtering and then copper (Cu) plating to fill the TDV holes. Subsequently, chemical mechanical polish (CMP) can be utilized to remove the overburden Cu and complete the build of the TDVs 801. Redistribution layer (RDL) 803, for example, a micrometer-level fine-line RDL with proper surface finish can be formed on a front-side 800F of the diamond substrate 800. Because the interposer illustrated in FIG. 18 is very thin, prior to forming another RDL 805 on the opposite side of the diamond substrate 800, a carrier 807 (e.g., typically a glass substrate which is commonly used in fan-out processing) is bonded to the RDL 803 of the interposer through the use of, for instance, an release layer 809 which can withstand the high temperatures incurred during the formation of the typically polyimide based RDL, followed by a thinning operation involving CMP and DRIE with the use of a sacrificial silicon dioxide layer as needed, which exposes and reveals the TDVs 801 at the backside 800B of the diamond substrate 800. After formation of the RDL 805, the resultant structure can be mounted on a wafer mount tape/frame to prepare the structure for dicing, and the carrier 807 can be removed by, for example, shinning a laser at the release layer 809 (or other means including thermo-mechanical shearing), followed by a dicing operation as needed including mechanical dicing, laser dicing, plasma etch, wet etch or a combination thereof to singulate the diamond substrate 800 so as to obtain diamond interposers and spacers of desired dimensions to be used in forming the package structures described herein.

People having ordinary skill in the art shall appreciate that the procedures described in FIG. 18 also applies to fabrication of diamond-based or other HTC material-based integrated circuit, in addition to interposers.

FIGS. 19 to 20 provide advanced ICs that can be created by diamond-based composite wafers (e.g., diamond-on-Si, bi-wafers and tri-wafers). In FIG. 19, a full-sized reconstituted silicon-diamond bi-wafer 600 (e.g., 12″) is first provided, followed by DRIE into the silicon portion, i.e., the device layer, of the bi-wafer 600 using fluorinated gases such as CF₄, SF₆ or xenon difluoride (i.e., the so-called Bosch etch process) as the etch gas to create the through-silicon via (TSV) holes (not shown) and this process can be carried out in conjunction with the IC's FEOL and BEOL processing of the composite wafer. Subsequently, diamond holes directly underneath the TSV holes can be opened using the process described in FIG. 18 to create through-diamond via (TDV) holes in the diamond portion of the bi-wafer 600 underneath the TSV holes, thereby forming the through-silicon-diamond via (TSDV) holes (not shown). Subsequently, one can resume and follow the balance of the diamond interposer process described in FIG. 18 from the PECVD, and PVD (e.g., sputtering) steps for passivation and barrier/seed layer deposition, copper (Cu) plating to fill the TSDV holes, and CMP to remove the overburden Cu and complete the build of TSDVs 601. RDL 603 can then be formed on a front-side 600F (e.g., surface of the silicon portion) of the bi-wafer 600 connecting to the TSDVs 601. Because the bi-wafer IC in FIG. 19 can be very thin, prior to forming another RDL 605 at an opposite side of the bi-wafer 600, a carrier 607 (e.g., typically a glass substrate which is commonly used in fan-out processing) is bonded to the RDL 603 of the bi-wafer IC through a release layer 609 which can withstand the high temperatures incurred during the formation of the typically polyimide based RDL, followed by a thinning operation involving CMP and DRIE with or without the use of an oxide sacrificial layer as needed which exposes and reveals the TSDVs 601 at the backside 600B of the bi-wafer 600. After formation of the RDL 605 with proper surface finish and bonding pads (e.g., micro-bumps) and mounting of the resultant structure to a wafer mounting tape/frame, the carrier 607 can be removed by shinning a laser at the release layer 609 or other means including thermos-mechanical shearing, wet cleaning or a combination thereof, and the resultant structure can be diced or singulated as needed by a dicing operation including mechanical dicing, laser dicing, plasma etch, wet etch or a combination thereof to singulate the bi-wafer 600 so as to obtain silicon-diamond ICs (or interposers and spacers) of desired dimensions to be used in the package structures described herein.

Similar operations in FIG. 19 on bi-wafer IC fabrication can be applied to a tri-wafer scheme as illustrated in FIG. 20, which is more suitable for the formation of, for example, thin processor or memory die containing a thin device layer based on silicon, a thin diamond layer placed in close proximity to the device layer for heat dissipation from chip hot spots and a thicker silicon carrier layer to facilitate thin film wafer-level processing. A full-sized silicon-diamond-silicon tri-wafer 700 (e.g., 12″) is first provided, followed by DRIE in one of the silicon portions, i.e., the device layer, of the tri-wafer 700 using fluorinated gases such as CF₄, SF₆ or xenon difluoride (i.e., the so-called Bosch etch process) as the etch gas to create the through-silicon via (TSV) holes (not shown) and this process can be carried out in conjunction with the IC's FEOL and BEOL processing of the composite wafer. Subsequently, the diamond underneath the TSV holes can be opened partially or all the way through using the process described in FIG. 18 to create through-diamond via (TDV) holes in the diamond portion of the tri-wafer 700 on where the TSV holes are with the assistance of alignment marks as needed, and thereby forming the through-silicon-diamond via (TSDV) holes (not shown). Subsequent to this, one can then resume the balance of the diamond interposer process described in FIG. 18 from the PECVD and PVD (e.g., sputtering) steps for passivation and barrier/seed deposition, copper (Cu) plating to form the TSDVs, CMP and DRIE as needed to remove the overburden Cu to complete the build of TSDVs 701. RDL 703 can subsequently be formed on a front-side 700F of the tri-wafer 700. When the tri-wafer IC in FIG. 20 is very thin, prior to forming another RDL 705 on the opposite side of the tri-wafer 700, a carrier 707 (e.g., typically a glass substrate which is commonly used in fan-out processing) is bonded to the RDL 703 of the tri-wafer IC through a release layer 709 which can withstand the high temperatures incurred during the formation of the typically polyimide based RDLs, and the silicon carrier portion of the tri-wafer 700 is removed during the planarization process involving CMP and DRIE with or without the use of a sacrificial layer such as silicon dioxide as needed to reveal the TSDVs. After formation of the RDL 705 over the exposed diamond portion and the TSDVs 701, the carrier 707 can be removed following wafer mounting by shinning a laser at the release layer 709 or other suitable means, followed by a dicing or singulation operation to singulate the ICs so as to obtain silicon-diamond ICs of desired dimensions to be used in the package structures described herein.

FIGS. 21A to 21C show a process flow to create the BSPDN structure enhanced with a HTC supporter such as a diamond interposer or an interposer based on other high-TC materials without the second silicon substrate such that the second silicon substrate side of the HTC-processor combo can be mounted and interconnected with the HBM DRAM stacks with or without the use of a RDL. In FIG. 21A, a first semiconductor substrate 501 is bonded to a second semiconductor substrate 502 through a pair of bonding layers 503, for example, dielectric bonding layers. Optionally, each of the first semiconductor substrate 501 and the second semiconductor substrate 502 includes a respective buffer stop layer 501B, 502B between the active region and the bulk region. In the first semiconductor substrate 501, a buried power rail 5011 is formed prior to the creation of a front-end-of-line (FEOL) structure 5012 of the processor IC, and the semiconductor is later stacked with a local interconnect 5013, an intermediate interconnect 5014 and optionally a RDL (not shown in FIG. 21A) or a bonding layer. The local interconnect 5013, the intermediate interconnect 5014 and the RDL can be a portion of a back-end-of-line (BEOL) structure of the processor IC with distinguishable line width and line spacing. The second semiconductor substrate 502 is typically attached to the intermediate interconnect 5014 through the bonding layers 503 for structural integrity since the first semiconductor substrate 501 used in building the processor IC will be subsequently thinned to less than 5 μm by suitable wafer grinding/thinning operations, chemical mechanical polishing (CMP) operations, dry and/or wet etch operations, or a combination thereof—while leaving the active silicon region and the power rail intact as shown in FIG. 21A.

Subsequently and as shown in FIG. 21B, a backside passivation 504 is deposited by, for example, thermal oxidation or PECVD, and forming a layer of silicon oxide. Nano-TSVs 5051 are then formed at the backside of the processor IC to establish electrical connections with the buried power rail 5011. Thermal vias 1012 may be formed at the backside of the processor IC at various locations proximal to the heat sources, for example, to the FEOL structure 5012, the nano TSVs 5051, and/or the buried power rail 5011. A global interconnect 8011 (and optionally RDL 803A), which is devised to provide power and signaling to processor IC through the backside of the processor IC with BSPDN, can then be formed over the nano-TSVs 5051 connecting the thermal vias 1012 to the global interconnect (and RDL 803A) on the backside of the processor IC. The global interconnect 8011 is a general term to include power traces and signal traces routed to the FEOL 5012 structure of the processor IC.

In FIG. 21C, a pre-fabricated first supporter 103 (using, for instance, the processes shown in FIG. 18), for example a diamond interposer or any other suitable HTC-based component, with an RDL 803B on a first side facing the backside of the processor IC and an RDL 803C on a second side opposite to the first side, is then bonded through copper hybrid bonding based on, for example, oxide-to-oxide bonding to the processor IC through RDL 803A or the global interconnect previously formed thereon. The bonding layers hereby connecting the first supporter 103 to the processor IC can be hybrid bonding layers. The first supporter 103 or the diamond interposer in some embodiments may possess a plurality of TDVs serving distinguishable purposes. For example, a thermal via 103A in the first supporter 103 connecting the RDL 803B and RDL 803C is thermally coupled to the thermal vias 1012 previously formed in the processor IC. For another example, a power via and a signal via 103B (collectively a power/signal via) in the first supporter 103 connecting the RDL 803B and RDL 803C is electrically connected to the power traces and signal traces of the global interconnect 8011 and then to the FEOL 5012 structure of the processor IC. Contact terminals 507 such as micro-bumps can then be formed on the RDL 803C of the first supporter 103. In the next step, the second semiconductor substrate 502, including the bulk semiconductor, the buffer stop layer 502B, and the bonding layers 503, is removed by suitable planarization and etch operations, followed by formation of RDL 803D containing suitable surface finish for bonding as needed over the intermediate interconnect 5014. FIG. 22 shows manufacturing operations to form a thermal isolation layer and/or a thermal spreading layer in suitable interconnect layers and structures of the semiconductor packages described herein. A thermal isolation layer or structure 901 can be formed adjacent to predetermined active regions, for example, between a memory cache region 900A and a hot core region 900B of a processor IC, in a form of one or more trenches or holes and prior to or during the CMOS FEOL processing. In some embodiments, the thermal isolation layer 901 can include a thermal metamaterial structure such as silica/graphene/Si/graphene/silica created during FEOL processing or ultra-thin (e.g., 2 nm) nano-materials such as graphene on MoSe₂, MoS₂ and WSe₂ hetero-structures deposited by vacuum processes in isolation trenches for better heat management. A thermal isolation structure such as graphene on MoSe₂, MoS₂ and WSe₂ hetero-structures can possess high thermal isolation property with thermal resistance greater than 100 times of SiO₂ in comparable thickness and effective thermal conductivity lower than air at room temperature. In addition, the thermal isolation layer and/or a thermal spreading layer 903 can be deposited in BEOL structure in a form of conductive traces or three dimensional metamaterial structure. Heat spreading materials can include graphene, carbon nanotube, diamond, boron nitride and/or boron arsenide. The thermal isolation layer and/or a thermal spreading layer 903 can then be patterned by suitable lithography operations, and be encapsulated by a suitable dielectric material, and routed with connection to thermal vias through proper lithography operations such as via hole/trench patterning in the dielectric layer and contact metallization.

Referring to FIG. 21C and FIG. 22, the thermal isolation layer and/or a thermal spreading layer illustrated in FIG. 22 can be formed in the RDLs, the BEOL structures of the processor IC such as the local interconnect 5013, the intermediate interconnect 5014 and the global interconnect 8011 proximal to the front side of the processor IC, and the FEOL structure 5012 of the processor IC.

One aspect of the present disclosure is to provide a semiconductor package including a first die having a front side and a backside, a substrate carrying the first die with the substrate having a first cavity allowing a liquid coolant to pass through, and a cold plate over the first die with the cold plate having a second cavity configured to connect to the first cavity and allowing the liquid to flow between the first cavity and the second cavity.

Another aspect of the present disclosure is to provide a semiconductor package including a processor die having a front side and a backside, a plurality of memory dies and control dies stacked over the processor die, a substrate carrying the processor die, the memory dies, and the control dies with the substrate having a first cavity allowing a liquid coolant to pass through, and a cold plate over the processor die, the memory dies, and the control dies, with the cold plate having a second cavity configured to connect to the first cavity, thereby allowing the liquid coolant to flow between the first cavity and the second cavity. The cold plate is in direct thermal contact with the processor die, a top die of the memory dies or the control dies.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first die having a front side and a backside;
a substrate carrying the first die with the substrate comprising a first cavity allowing a liquid to pass through; and
a cold plate over the first die with the cold plate comprising a second cavity configured to connect to the first cavity and allowing the liquid to flow between the first cavity and the second cavity.

2. The semiconductor package of claim 1, wherein the substrate further comprises:
an upper portion defining a first part of the first cavity;
a lower portion defining a second part of the first cavity; and
a bonding structure connecting the upper portion and the lower portion of the substrate,
wherein the first part and the second part of the first cavity combined is configured to form a fluidic channel allowing the liquid to pass through.

3. The semiconductor package of claim 2, wherein the bonding structure further comprises:
a first sealing structure on a surface of the upper portion facing the lower portion of the substrate;
a second sealing structure on a surface of the lower portion facing the upper portion of the substrate, wherein the second sealing structure geometrically matches the first sealing structure; and
a bonding material connecting the first sealing structure and the second sealing structure.

4. The semiconductor package of claim 3, wherein the substrate further comprises:
a first interconnect layer facing toward the first die;
a second interconnect layer facing away from the first die;
a through via electrically, optically, or thermally coupling the first interconnect layer and the second interconnect layer; and
an isolation structure proximal to the first sealing structure and the second sealing structure, configured to isolate the through via from the first sealing structure and the second sealing structure.

5. The semiconductor package of claim 1, further comprising:
a plurality of second dies stacked over or disposed side-by-side with the first die; and
a structural member disposed side-by-side with the first die and the second dies, the structural member comprising a third cavity configured to connect to the first cavity and the second cavity, allowing for the liquid to flow between the first cavity, the second cavity, and the third cavity,
wherein the cold plate is in direct thermal contact with at least one of a top die of the second dies or the first die.

6. The semiconductor package of claim 5, further comprising:
a first supporter disposed in between the first die and the substrate, and thermally coupled to the first die and the substrate, wherein a thermal conductivity of the first supporter is greater than a thermal conductivity of the first die.

7. The semiconductor package of claim 6, wherein the first supporter comprises an interposer composed of a material with a thermal conductivity greater than that of silicon, and with the interposer having a cross sectional width greater than or substantially identical to a cross sectional width of the first die.

8. The semiconductor package of claim 6, wherein the first supporter and the first die combined form a composite layer with at least one via passing through the first die and the first supporter.

9. The semiconductor package of claim 6, wherein the first supporter is composed of diamond, graphene, boron nitride, boron arsenide, cubic boron arsenide, aluminum nitride, silicon carbide, or a combination thereof, and the substrate is composed of silicon, diamond, graphene, boron nitride, boron arsenide, cubic boron arsenide, aluminum nitride, silicon carbide, or a combination thereof.

10. The semiconductor package of claim 6, wherein the backside of the first die is located in close proximity to the first supporter and the front side of the first die is farther away from the first supporter compared to the backside.

11. The semiconductor package of claim 10, further comprising:
a global interconnect disposed on the backside of the first die;
a first re-distribution layer (RDL) disposed on the global interconnect; and
a second RDL on a first side of the first supporter facing the first die,
wherein the first die and the first supporter are bonded through the first RDL and the second RDL.

12. The semiconductor package of claim 11, further comprising:
a buried power rail proximal to a front-end-of-line structure of the first die;
a power trace and a signal trace in the global interconnect, electrically connected to the buried power rail, to the FEOL structure and to the first supporter.

13. The semiconductor package of claim 12, further comprising:
a third RDL on a second side of the first supporter opposite to the first side;
a first thermal via in the first supporter, connecting the second RDL and the third RDL;
a first power via and a first signal via in the first supporter, connecting the second RDL and the third RDL; and
a second thermal via proximal to the power trace and the signal trace in the global interconnect and the FEOL structure of the first die, wherein the second thermal via is thermally coupled to the first thermal via in the first supporter.

14. The semiconductor package of claim 6, further comprising:
a second supporter between the first die and one of the second dies, or between adjacent second dies, wherein the second supporter comprises an interposer composed of a material with a thermal conductivity greater than that of silicon; and
a through via in the second supporter.

15. The semiconductor package of claim 14, further comprising:
a heat spreading layer or a thermal isolation layer in respective interconnect structure of the first supporter, the second supporter, the second dies, or a combination thereof.

16. The semiconductor package of claim 5, further comprising:
a flexible circuit interconnect electrically connecting the substrate or an electronic component underneath the substrate to a circuit layer proximal to the cold plate with the flexible circuit interconnect configured to provide power or signaling to at least one of the second dies or the front side of the first die.

17. A semiconductor package, comprising;
a processor die having a front side and a backside;
a plurality of memory dies and control dies stacked over the processor die;
a substrate carrying the processor die, the memory dies, and the control dies with the substrate comprising a first cavity allowing a liquid to pass through; and
a cold plate over the processor die, the memory dies, and the control dies, with the cold plate comprising a second cavity configured to connect to the first cavity and allowing the liquid to flow between the first cavity and the second cavity,
wherein the cold plate is in direct thermal contact with the processor die, a top die of the memory dies or the control dies.

18. The semiconductor package of claim 17, wherein the substrate further comprises:
an upper portion defining a first part of the first cavity;
a lower portion defining a second part of the first cavity; and
a bonding structure connecting the upper portion and the lower portion of the substrate,
wherein the first part and the second part of the first cavity combined is configured to form a fluidic channel allowing the liquid to pass through.

19. The semiconductor package of claim 18, further comprising:
a first high thermal conductivity (HTC) structure disposed in between the processor die and the substrate, and thermally coupled to the processor die and the substrate, wherein a thermal conductivity of the first HTC structure is greater than a thermal conductivity of the processor die;
a second HTC structure between the processor die and control dies or between adjacent memory dies, wherein a thermal conductivity of the second HTC structure is greater than the thermal conductivity of the processor die;
a first structural member disposed side-by-side with the processor die, the memory dies, and the control dies with the first structural member comprising a third cavity configured to connect to the first cavity and the second cavity, allowing the liquid to flow between the first cavity, the second cavity, and the third cavity; and
a second structural member disposed side-by-side with the processor die, the plurality of memory dies or the control dies, wherein the second structural member is stacked with the second HTC structure.

20. The semiconductor package of claim 19, further comprising:
spacer interconnects between the processor die and the plurality of memory dies and control dies;
an air gap defined by the spacer interconnects, the processor die, and the control dies, wherein the control dies govern interconnections between the processor die and the memory dies;
a redistribution layer (RDL) with conductive traces over a front side of the processor die; and
a heat spreading layer or a thermal isolation layer in respective interconnect structure of the processor die, the control dies, the memory dies, the first HTC structure, the second HTC structure, or a combination thereof.
